(19) United States
(12) Patent Application Publication
(10) Pub. No.: US 2026/0122375 A1
(43) Pub. Date: Apr. 30, 2026

(54) PHOTODETECTION DEVICE, DISTANCE MEASURING DEVICE, AND METHOD FOR CONTROLLING PHOTODETECTION DEVICE

(71) Applicant: SONY SEMICONDUCTOR SOLUTIONS CORPORATION, KANAGAWA (JP)

(72) Inventors: DAN LUO, KANAGAWA (JP); KEISUKE UMAKOSHI, KANAGAWA (JP); KENJI OBA, KANAGAWA (JP); YUYA MAEKAWA, KANAGAWA (JP)

(21) Appl. No.: 19/119,412

(22) PCT Filed: Aug. 22, 2023
(86) PCT No.: PCT/JP2023/030081

§ 371 Date: Apr. 9, 2025

(30) Foreign Application Priority Data
Oct. 17, 2022 (JP) 2022-166334

(51) Int. Cl. H04N 25/773; G01S 17/10; G01S 17/894; H04N 25/705; H04N 25/76

(52) U.S. Cl. CPC H04N 25/773; G01S 17/10; G01S 17/894; H04N 25/705; H04N 25/7795

(57) ABSTRACT

A circuit area is reduced in a photodetection device in which a plurality of pixels is arranged. A first detection circuit detects incidence of photons on the basis of a voltage of one of an anode and a cathode of a first photoelectric conversion element within a period not corresponding to a predetermined detection stop period. A second detection circuit detects incidence of photons on the basis of a voltage of one of an anode and a cathode of a second photoelectric conversion element within a period not corresponding to the detection stop period. A shared circuit controls a voltage of a gating pulse indicating the detection stop period.

### TECHNICAL FIELD

The present technology relates to a photodetection device. Specifically, the present technology relates to a photodetection device that measures a distance to an object, a distance measuring device, and a method for controlling the photodetection device.

### BACKGROUND ART

Conventionally, in an electronic device having a distance measuring function, a distance measuring method called a time of flight (ToF) method is known. The ToF method is a method of measuring a distance by irradiating an object with irradiation light from an electronic device and obtaining a round-trip time until the irradiation light is reflected and returned to the electronic device. For detection of the reflected light with respect to the irradiation light, a single-photon avalanche diode (SPAD) is often used as a photoelectric conversion element. For example, a photodetection device has been proposed in which a pixel provided with a SPAD having a wide light receiving area and a pixel provided with a SPAD having a narrow light receiving area are arranged (see, for example, Patent Document 1).

### CITATION LIST

### Patent Document

Patent Document 1: Japanese Patent Application Laid-Open No. 2022-092345

### SUMMARY OF THE INVENTION

### Problems to be Solved by the Invention

In the above-described conventional technology, a dynamic range is expanded by processing signals from two types of SPADs having different light receiving areas. However, in the above-described device, it is necessary to arrange a large number of elements such as a current source and a switch in addition to the SPAD for each pixel, and it is difficult to reduce a circuit area per pixel.

The present technology has been made in view of such a situation, and an object thereof is to reduce a circuit area in a photodetection device in which a plurality of pixels is arranged.

### Solutions to Problems

The present technology has been made to solve the above-described problems, and a first aspect thereof is a photodetection device including: a first detection circuit that detects incidence of photons on the basis of a voltage of one of an anode and a cathode of a first photoelectric conversion element within a period not corresponding to a predetermined detection stop period; a second detection circuit that detects incidence of photons on the basis of a voltage of one of an anode and a cathode of a second photoelectric conversion element within a period not corresponding to the detection stop period; and a shared circuit that controls a voltage of a gating pulse indicating the detection stop period, and a method for controlling the photodetection device. This brings about an effect that the circuit area per pixel is reduced.

Furthermore, in the first aspect, the first and second detection circuits may output at least one of a first pulse signal or a second pulse signal according to a selection signal in a case where incidence of photons is detected, and the shared circuit may include a gating control circuit that controls a voltage of the gating pulse, and a selection circuit that generates the selection signal and supplies the selection signal to the first and second detection circuits. This brings about an effect that the circuit area is further reduced.

Furthermore, in the first aspect, the gating control circuit may include a pre-stage inverter that inverts the gating pulse and outputs an inverted signal, and a post-stage inverter that inverts the inverted signal and supplies a result to the first and second detection circuits, and power supply voltages of the pre-stage inverter and the post-stage inverter may be different from each other. This brings about an effect that the power supply voltage of the gating pulse is controlled.

Furthermore, in the first aspect, the gating control circuit may include an inverter that inverts the gating pulse and outputs the inverted gating pulse as an enable signal, a logic gate that performs a logic operation on a pulse signal from each of the first and second detection circuits and outputs an operation result, and a flip-flop that supplies a signal at a predetermined level to the first and second detection circuits in synchronization with the operation result in a case where the enable signal has a predetermined value. This brings about an effect that the circuit scale of the detection path is reduced.

Furthermore, in the first aspect, the shared circuit may further include a recharge circuit that performs recharging of one of the first and second photoelectric conversion elements, an active quench switch that connects the recharge circuit and a reference voltage within the active quench period according to an active quench enable signal indicating a predetermined active quench period, and an active quench pulse generation circuit that generates the active quench enable signal. This brings about an effect that the circuit area is further reduced.

Furthermore, in the first aspect, the photodetection device may further include a recharge switching switch that selects one of the first and second photoelectric conversion elements and connects the selected one to the recharge circuit. The recharge circuit may include an active recharge current source, a passive recharge current source, an active recharge switch that opens and closes a path between the active recharge current source and the recharge switching switch according to an active recharge enable signal, and a passive recharge switch that opens and closes a path between the passive recharge current source and the recharge switching switch, and the shared circuit may further include an active recharge pulse generation circuit that generates the active recharge enable signal. This brings about an effect that instantaneous power consumption is reduced.

Furthermore, in the first aspect, the shared circuit may further include an active recharge start signal generation circuit that generates an active recharge start signal when the active quench period has elapsed or when the recharge switching switch is switched, and the active recharge pulse generation circuit may generate the active recharge enable signal on the basis of the active recharge start signal. This brings about an effect that the active quench period is reduced.

Furthermore, in the first aspect, the detection circuit may include an active recharge current source, an active recharge switch that opens and closes a path between the active recharge current source and a predetermined node according to an active recharge enable signal, an active quench switch that connects the predetermined node and a reference voltage within a predetermined active quench period, and an active recharge pulse generation circuit that generates the active recharge enable signal when the detection stop period has elapsed or when the active quench period has elapsed. This brings about an effect that the dead time is shortened.

Furthermore, in the first aspect, the photoelectric conversion element may be a single-photon avalanche diode (SPAD). This brings about an effect that incidence of photons is detected.

Furthermore, a second aspect of the present technology is a distance measuring device including: a light emitting unit; and a photodetection element including a first detection circuit that detects incidence of photons on the basis of a voltage of one of an anode and a cathode of a first photoelectric conversion element within a period not corresponding to a predetermined detection stop period, a second detection circuit that detects incidence of photons on the basis of a voltage of one of an anode and a cathode of a second photoelectric conversion element within a period not corresponding to the detection stop period, a shared circuit that controls a voltage of a gating pulse indicating the detection stop period, and a distance measuring unit that performs distance measurement on the basis of a light emission timing of the light emitting unit and an incidence timing of the photons detected by each of the first and second detection circuits. This brings about an effect that the circuit area per pixel is reduced in the distance measuring device.

### BRIEF DESCRIPTION OF DRAWINGS

FIG. 1 is a block diagram illustrating a configuration example of a distance measuring module in a first embodiment of the present technology.

FIG. 2 is a diagram illustrating an example of a stacked structure of a photodetection element in the first embodiment of the present technology.

FIG. 3 is a plan view illustrating a configuration example of a pixel chip in the first embodiment of the present technology.

FIG. 4 is a block diagram illustrating a configuration example of a circuit chip in the first embodiment of the present technology.

FIG. 5 is a plan view illustrating an example of a circuit layout in a circuit block in the first embodiment of the present technology.

FIG. 6 is a diagram illustrating a configuration example of a pixel in the first embodiment of the present technology.

FIG. 7 is a block diagram illustrating a configuration example of a detection circuit in the first embodiment of the present technology.

FIG. 8 is a circuit diagram illustrating a configuration example of a gating circuit and a latch signal generation circuit in the first embodiment of the present technology.

FIG. 9 is a circuit diagram illustrating a configuration example of an AR pulse generation circuit, an AQ pulse generation circuit, and an output control circuit in the first embodiment of the present technology.

FIG. 10 is a circuit diagram illustrating a configuration example of a shared circuit in the first embodiment of the present technology.

FIG. 11 is a timing chart illustrating an example of an operation of a pixel in the first embodiment of the present technology.

FIG. 12 is a diagram for describing an example of control of a decoder in the first embodiment of the present technology.

FIG. 13 is a view illustrating a wiring example of a signal line for transmitting a gating pulse in a first comparative example.

FIG. 14 is a diagram illustrating a wiring example of a signal line for transmitting a gating pulse in the first embodiment of the present technology.

FIG. 15 is a diagram illustrating a wiring example of a signal line for transmitting a gating pulse in a shared block in the first embodiment of the present technology.

FIG. 16 is a diagram illustrating a wiring example of a signal line for transmitting a decoded signal in the first comparative example.

FIG. 17 is a diagram illustrating a wiring example of a signal line for transmitting a decoded signal in the first embodiment of the present technology.

FIG. 18 is a diagram illustrating a wiring example of a signal line for transmitting a decoded signal in a shared block in the first embodiment of the present technology.

FIG. 19 is a diagram illustrating a wiring example of a signal line for transmitting a gating pulse when a shared circuit is shared by 16 pixels in the first embodiment of the present technology.

FIG. 20 is a diagram illustrating a wiring example of a signal line for transmitting a decoded signal when a shared circuit is shared by 16 pixels in the first embodiment of the present technology.

FIG. 21 is a circuit diagram illustrating a configuration example of a detection circuit and a shared circuit in a first modification of the first embodiment of the present technology.

FIG. 22 is a circuit diagram illustrating a configuration example of a detection circuit and a shared circuit in a second modification of the first embodiment of the present technology.

FIG. 23 is a block diagram illustrating a configuration example of a detection circuit in a second embodiment of the present technology.

FIG. 24 is a circuit diagram illustrating a configuration example of an AR pulse generation circuit and an AQ pulse generation circuit in the second embodiment of the present technology.

FIG. 25 is an example of a timing chart illustrating each of active recharge control in the second embodiment of the present technology and active recharge control in the first embodiment.

FIG. 26 is a circuit diagram illustrating a configuration example of a detection circuit in a third embodiment of the present technology.

FIG. 27 is a block diagram illustrating a configuration example of a shared circuit in the third embodiment of the present technology.

FIG. 28 is a diagram illustrating an example of an operation of a recharge switching control unit in the third embodiment of the present technology.

FIG. 29 is a timing chart illustrating an example of an operation of a detection circuit in a second comparative example.

FIG. 30 is a timing chart illustrating an example of an operation of the shared circuit in a case where photons are incident on each pixel in sequence in the third embodiment of the present technology.

FIG. 31 is a timing chart illustrating an example of an operation of the shared circuit in a case where photons are incident on two pixels almost simultaneously in the third embodiment of the present technology.

FIG. 32 is a timing chart illustrating an example of operation of the shared circuit in a case where photons are incident on two pixels almost simultaneously and then photons are incident on one pixel in the third embodiment of the present technology.

FIG. 33 is a diagram illustrating an example of a circuit layout in the detection circuit in the second comparative example.

FIG. 34 is a diagram illustrating an example of a circuit layout in the shared circuit in the third embodiment of the present technology.

FIG. 35 is a circuit diagram illustrating a configuration example of a shared circuit in a modification of the third embodiment of the present technology.

FIG. 36 is a circuit diagram illustrating a configuration example of an AR start signal generation circuit in the modification of the third embodiment of the present technology.

FIG. 37 is a timing chart illustrating an example of an operation of the shared circuit when one of two pixels detects photons in the modification of the third embodiment of the present technology.

FIG. 38 is a timing chart illustrating an example of an operation of the shared circuit when the other of the two pixels detects photons in the modification of the third embodiment of the present technology.

FIG. 39 is a timing chart illustrating an example of an operation of the shared circuit when the other reacts within an active quench period of one of the two pixels in the modification of the third embodiment of the present technology.

FIG. 40 is a timing chart illustrating an example of an operation of the shared circuit in a case where photons are incident on two pixels almost simultaneously and then photons are incident on one pixel in the modification of the third embodiment of the present technology.

FIG. 41 is a timing chart illustrating an example of an operation of the shared circuit when the other reacts during recharging of one of two pixels in the modification of the third embodiment of the present technology.

FIG. 42 is a block diagram illustrating a schematic configuration example of a vehicle control system.

FIG. 43 is an explanatory diagram illustrating an example of an installation position of an imaging section.

### MODE FOR CARRYING OUT THE INVENTION

Modes for carrying out the present technology (hereinafter, referred to as embodiments) will be described below. The description will be given in the following order.
1. First Embodiment (example of sharing gating control Circuit)
2. Second Embodiment (example of sharing gating control circuit and performing active recharging when detection stop period has elapsed)
3. Third Embodiment (example of sharing gating control circuit, recharge circuit, and like)
4. Example of Application to Mobile Body

### 1. First Embodiment

### Configuration Example of Distance Measuring Module

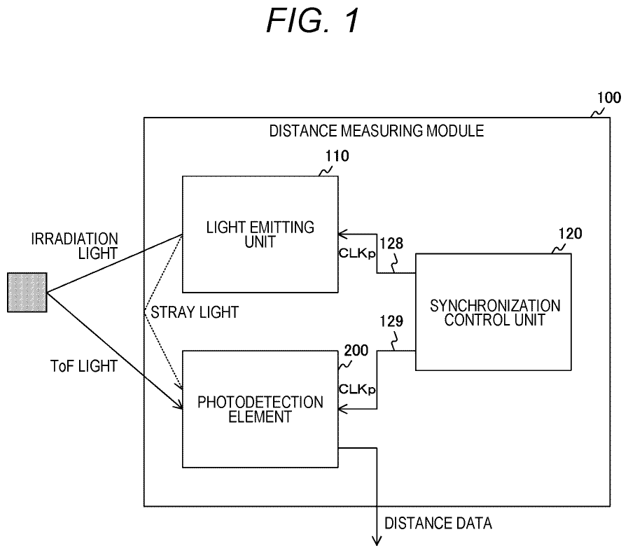

FIG. 1 is a block diagram illustrating a configuration example of a distance measuring module 100 in a first embodiment of the present technology. The distance measuring module 100 measures a distance to an object, and includes a light emitting unit 110, a synchronization control unit 120, and a photodetection element 200. The distance measuring module 100 is mounted on a smartphone, a personal computer, an in-vehicle device, or the like, and is used to measure a distance.

The synchronization control unit 120 operates the light emitting unit 110 and the photodetection element 200 in synchronization. The synchronization control unit 120 supplies a clock signal of a predetermined frequency (such as 10 to 20 megahertz) as a synchronization signal CLKp to the light emitting unit 110 and the photodetection element 200 via signal lines 128 and 129.

The light emitting unit 110 supplies intermittent light as irradiation light in synchronization with the synchronization signal CLKp from the synchronization control unit 120. For example, near-infrared light or the like is used as the irradiation light. When the irradiation light is reflected by a measurement target, the reflected light is hereinafter referred to as “ToF light”.

The photodetection element 200 receives the ToF light by a photoelectric conversion element (SPAD or the like) and measures a round-trip time from the light emission timing indicated by the synchronization signal CLKp to the light reception timing of the ToF light. The photodetection element 200 calculates a distance to a target from the round-trip time, and generates and outputs distance data indicating the distance.

Furthermore, when the irradiation light is reflected inside a housing of the distance measuring module 100 without hitting the target, the reflected light is hereinafter referred to as “stray light”. By the photodetection element 200 obtaining a difference between the light reception timing of the stray light and the light reception timing of the ToF light, a signal delay or the like in the distance measuring module 100 can be canceled, and a distance measuring accuracy can be improved.

However, due to the characteristics of the SPAD, when the incidence of photons is detected, it is not possible to detect the incidence of new photons within a certain dead time from the detected timing. For this reason, if the SPAD detects the stray light, the ToF light reflected at a short distance cannot be detected due to the occurrence of the dead time, and it becomes difficult to measure the short distance. In this regard, it is necessary to control to forcibly stop the detection of photons within a certain period in which the stray light occurs. This control is referred to as “gating”, and a period in which the detection of photons is forcibly stopped by gating is referred to as “detection stop period”.

Note that, although the light emitting unit 110, the photodetection element 200, and the synchronization control unit 120 in the distance measuring module 100 are arranged in the same module, they may be arranged in separate devices. A device in which the photodetection element 200 is arranged is an example of a photodetection device described in the claims.

### Configuration Example of Photodetection Element

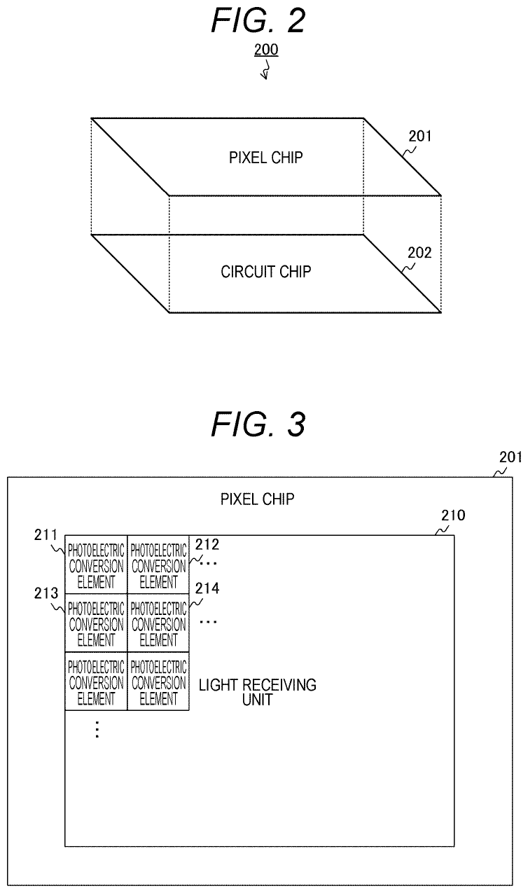

FIG. 2 is a diagram illustrating an example of a stacked structure of the photodetection element 200 in the first embodiment of the present technology. The photodetection element 200 includes a circuit chip 202 and a pixel chip 201 stacked on the circuit chip 202. These chips are electrically connected to each other via a connection unit such as a via. Note that the chips can be connected by Cu—Cu bonding or a bump instead of a via.

FIG. 3 is a plan view illustrating a configuration example of the pixel chip 201 in the first embodiment of the present technology. The pixel chip 201 is provided with a rectangular light receiving unit 210, and a plurality of photoelectric conversion elements such as photoelectric conversion elements 211, 212, 213, and 214 is arranged in a two-dimensional lattice pattern in the light receiving unit 210. As the photoelectric conversion element, an avalanche photodiode such as a SPAD is used.

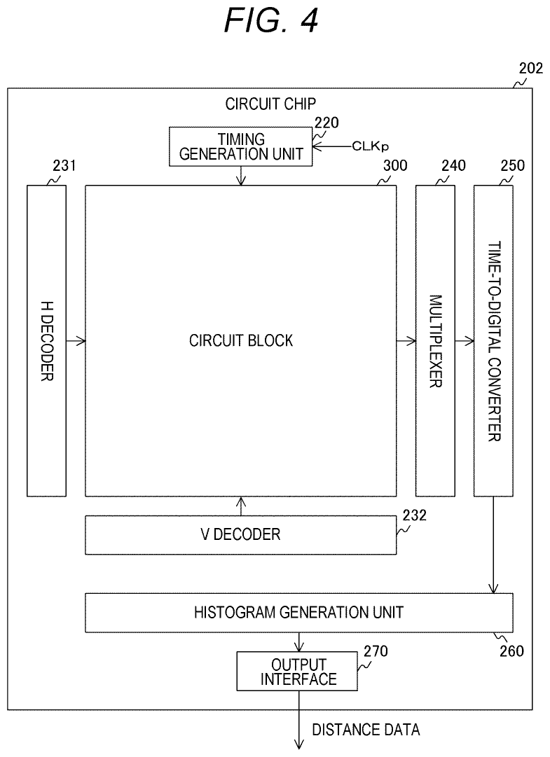

FIG. 4 is a block diagram illustrating a configuration example of the circuit chip 202 in the first embodiment of the present technology. The circuit chip 202 includes a timing generation unit 220, an H decoder 231, a V decoder 232, a circuit block 300, a multiplexer 240, a time-to-digital converter 250, a histogram generation unit 260, and an output interface 270.

The timing generation unit 220 generates various control signals in synchronization with the synchronization signal CLKp. The timing generation unit 220 supplies these signals to the circuit block 300. The control signal includes, for example, a gating pulse indicating a photon detection stop period.

In the circuit block 300, a plurality of detection circuits (not illustrated) is arranged. Each of the detection circuits detects incidence of photons, generates a pulse signal, and supplies the pulse signal to the multiplexer 240.

The H decoder 231 and the V decoder 232 drive circuits in the pixel block 300 in units of rows or columns.

The multiplexer 240 sequentially selects each row and supplies the pulse signal of the row to the time-to-digital converter 250.

The time-to-digital converter 250 converts the time to rise of the pulse signal into a digital signal for each row. This digital signal indicates a photon detection timing. The time-to-digital converter 250 supplies the digital signal to the histogram generation unit 260.

The histogram generation unit 260 generates a histogram on the basis of the digital signal from the time-to-digital converter 250. Here, the histogram is a graph indicating a detection frequency as a frequency for each detection timing indicated by the digital signal. The histogram generation unit 260 generates a histogram for each imaging pixel and obtains the timing of each peak value as the light reception timing of the reflected light. Then, the histogram generation unit 260 converts the round-trip time from the irradiation timing of the irradiation light indicated by the synchronization signal to the light reception timing of the reflected light into a distance to the object for each imaging pixel. The histogram generation unit 260 generates distance data indicating the obtained distance for each pixel and outputs the distance data to the outside via the output interface 270. Note that a circuit including the time-to-digital converter 250 and the histogram generation unit 260 is an example of a distance measuring unit described in the claims. Furthermore, a device provided with the light emitting unit 110 and the photodetection element 200 is an example of a distance measuring device described in the claims.

### Configuration Example of Circuit Block

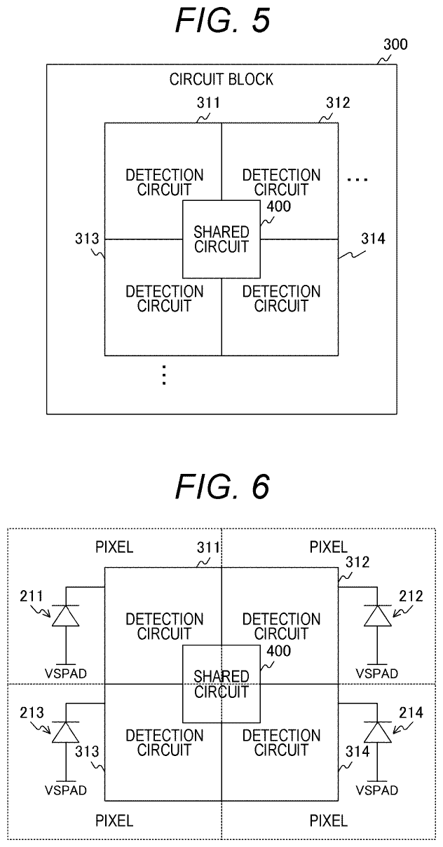

FIG. 5 is a plan view illustrating an example of a circuit layout in the circuit block 300 in the first embodiment of the present technology. In the circuit block 300, a plurality of detection circuits such as detection circuits 311, 312, 313, and 314 is arranged in a two-dimensional lattice pattern. These detection circuits are provided for each photoelectric conversion element. With the pixel chip 201 as a chip on the circuit chip 202, the detection circuit is arranged immediately below the corresponding photoelectric conversion element.

Furthermore, in the circuit block 300, one shared circuit 400 is arranged for every four detection circuits of 2 rows×2 rows. The shared circuit 400 is a circuit shared by four detection circuits, and is arranged at the center of 2 rows×2 columns.

FIG. 6 is a diagram illustrating a configuration example of a pixel in the first embodiment of the present technology. As described above, four detection circuits such as the detection circuits 311, 312, 313, and 314 share one shared circuit 400. Furthermore, each of the detection circuits is connected to a corresponding photoelectric conversion element.

For example, the detection circuit 311 and the photoelectric conversion element 211 are connected, and the detection circuit 312 and the photoelectric conversion element 212 are connected. Furthermore, the detection circuit 313 and the photoelectric conversion element 213 are connected, and the detection circuit 314 and the photoelectric conversion element 214 are connected.

The detection circuit 311 and the like detect incidence of photons outside the detection stop period on the basis of the cathode voltage of the corresponding photoelectric conversion element. In the shared circuit 400, a circuit for controlling the voltage of the gating pulse and the like are arranged.

The connected photoelectric conversion element and detection circuit, and the shared circuit 400 function as one pixel. For example, the photoelectric conversion element 211, the detection circuit 311, and the shared circuit 400 function as a first pixel, and the photoelectric conversion element 212, the detection circuit 312, and the shared circuit 400 function as a second pixel. The photoelectric conversion element 213, the detection circuit 313, and the shared circuit 400 function as a third pixel, and the photoelectric conversion element 214, the detection circuit 314, and the shared circuit 400 function as a fourth pixel. As illustrated in the drawing, the shared circuit 400 is shared by four pixels. The four pixels sharing the shared circuit 400 are referred to as a “shared block”.

Since a plurality of pixels shares the shared circuit 400, a circuit area for each pixel can be reduced as compared with a case where a plurality of pixels does not share the shared circuit.

### Configuration Example of Detection Circuit

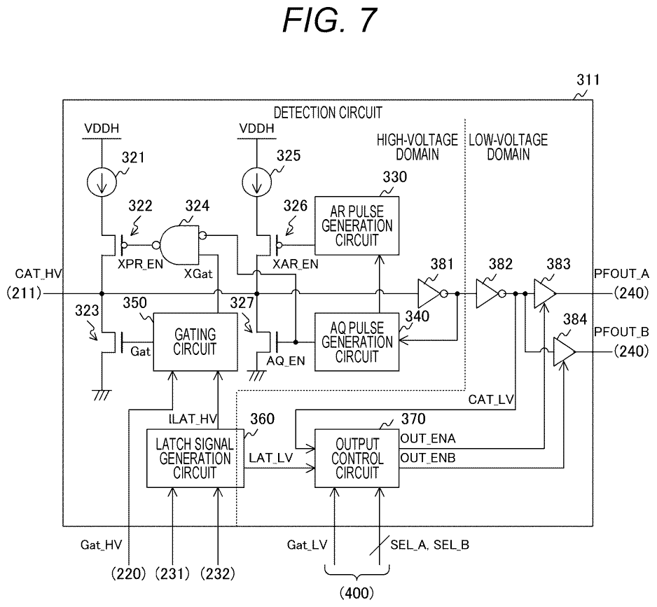

FIG. 7 is a block diagram illustrating a configuration example of the detection circuit 311 in the first embodiment of the present technology. The detection circuit 311 includes a passive recharge (PR) current source 321, a PR switch 322, a gating switch 323, a PR pulse generation circuit 324, a gating circuit 350, and a latch signal generation circuit 360. Furthermore, the detection circuit 311 includes an active recharge (AR) current source 325, an AR switch 326, an active quench (AQ) switch 327, an AR pulse generation circuit 330, and an AQ pulse generation circuit 340. Moreover, the detection circuit 311 includes inverters 381 and 382, buffers 383 and 384, and an output control circuit 370. Note that the circuit configuration of the detection circuits, such as the detection circuits 312, 313, and 314, other than the detection circuit 311 is similar to that of the detection circuit 311.

The passive recharge (PR) current source 321 supplies a constant current to the cathode of the photoelectric conversion element 211. The PR switch 322 opens and closes a path between the PR current source 321 and the cathode of the photoelectric conversion element 211 according to a PR enable signal XPR_EN from the PR pulse generation circuit 324. As the PR switch 322, for example, a p-channel metal oxide semiconductor (pMOS) transistor is used.

The PR pulse generation circuit 324 generates a PR enable signal XPR_EN. For example, a negative AND (NAND) gate that obtains a negative AND of a signal from the gating circuit 350 and an inverted value of an AQ enable signal AQ_EN from the AQ pulse generation circuit 340 is used as the PR pulse generation circuit 324. The NAND gate supplies a negative OR signal to the PR switch 322 as the PR enable signal XPR_EN.

Furthermore, the AR current source 325 supplies a constant current to the cathode of the photoelectric conversion element 211. The AR switch 326 opens and closes a path between the AR current source 325 and the cathode of the photoelectric conversion element 211 according to an AR enable signal XAR_EN from the AR pulse generation circuit 330. For example, a pMOS transistor is used as the AR switch 326.

The AR pulse generation circuit 330 generates an AR enable signal XAR_EN and supplies the generated signal to the AR switch 326.

The gating switch 323 opens and closes a path between the cathode of the photoelectric conversion element 211 and a reference potential (ground potential or the like) according to a gating pulse Gat from the gating circuit 350. As the gating switch 323, for example, an n-channel MOS (nMOS) transistor is used.

The gating circuit 350 generates a gating pulse Gat from a gating pulse Gat_HV from the timing generation unit 220 and a latch signal LAT_HV, and supplies the gating pulse Gat to the gating switch 323.

The latch signal generation circuit 360 generates the latch signals LAT_HV and LAT_LV on the basis of the signals from the H decoder 231 and the V decoder 232. The latch signal LAT_HV is supplied to the gating circuit 350, and the latch signal LAT_LV is supplied to the output control circuit 370. The H decoder 231 and the V decoder 232 can select pixels in units of rows and columns. The latch signal LAT_LV of the selected pixel is set to, for example, a high level.

The AQ switch 327 opens and closes a path between the cathode of the photoelectric conversion element 211 and the reference potential according to the AQ enable signal AQ_EN from the AQ pulse generation circuit 340. As the AQ switch 327, for example, an nMOS transistor is used.

The AQ pulse generation circuit 340 generates an AQ enable signal AQ_EN on the basis of the signal from the inverter 381, and supplies the AQ enable signal AQ_EN to the AQ switch 327 and the PR pulse generation circuit 324.

Here, the gating pulse described above is a signal indicating a detection stop period for forcibly stopping the detection of photons (in other words, performing gating). For example, the gating pulse is set to the high level during the detection stop period.

Furthermore, the AR enable signal XAR_EN is a signal indicating whether or not to enable active recharging. For example, when the active recharge is enabled, a low level is set to the AR enable signal XAR_EN.

The AQ enable signal AQ_EN is a signal indicating whether or not to enable active quenching. For example, the AQ enable signal is set to a high level when the active quenching is enabled.

The above-described active recharging and active quenching are functions for avoiding a latching phenomenon of a pixel. The latching phenomenon is a phenomenon in which, after detection of photons, a SPAD current due to avalanche multiplication does not decrease to a predetermined latching current, and an equilibrium state is obtained while a current flows. In a case where the recharge current for charging the SPAD is large, the voltage stagnates immediately before the quenching, and the latching is likely to occur. When the latching phenomenon occurs, the recharge current and the SPAD current due to avalanche multiplication continue to be balanced, and the cathode potential does not change. In this state, photons cannot be detected, and the dead time significantly increases.

In this regard, in the photodetection element 200, active quenching is performed as a countermeasure against the latching during the quenching. In a case where the recharge current is constantly allowed to flow, if the recharge current and the SPAD current are balanced, the latching cannot be released for a while. However, by detecting the reaction of the SPAD, stopping the recharge current for a certain period in the detection circuit 311, and performing “active quenching” of forcibly dropping the cathode voltage to 0 volt (V), it is possible to release the latching. Then, if the cathode voltage exceeds a threshold of the first-stage inverter 381 at the time of quenching, the latching does not occur.

Furthermore, in the photodetection element 200, active recharging is performed as a countermeasure against the latching during the recharging. In order to avoid the equilibrium state, after the SPAD reacts, the photodetection element 200 generates the AR enable signal XAR_EN, and performs “active recharging” of causing a recharge current to flow for a necessary time. Therefore, when the recharge period by the AR enable signal XAR_EN ends even if the latching occurs during the recharging, the recharge current becomes zero, the cathode voltage decreases by the SPAD current, and the latching is released.

On the other hand, in a case where the active recharging is not performed, the recharge current from the PR current source 321 is always supplied. This control is referred to as “passive recharging”. Then, in a case where the active quenching is not performed, the cathode voltage drops in response to incidence of photons, and if the latching does not occur, the SPAD current stops when the voltage becomes less than a breakdown voltage. This phenomenon is referred to as “passive quenching”.

The inverter 381 inverts the signal of the cathode voltage CAT_HV of the photoelectric conversion element 211 and supplies the inverted signal to the inverter 382 and the AQ pulse generation circuit 340. The inverter 382 inverts the signal from the inverter 381 and supplies the inverted signal as CAT_LV to the output control circuit 370 and the buffers 383 and 384.

The output control circuit 370 generates output enable signals OUT_ENA and OUT_ENB on the basis of the latch signal LAT_LV and the signal CAT_LV from the inverter 382. The output enable signals OUT_ENA and OUT_ENB are signals for enabling one of outputs of an A system and a B system. For example, in a case where the A system is enabled, the output enable signal OUT_ENA is set to a high level, and the output enable signal OUT_ENB is set to a low level. In a case where the B system is enabled, the output enable signal OUT_ENA is set to a low level, and the output enable signal OUT_ENB is set to a high level.

In a case where the output enable signal OUT_ENA is at a high level (enable), the buffer 383 outputs, as a pulse signal PFOUT_A, the signal from the inverter 382 to the multiplexer 240. In a case where the output enable signal OUT_ENB is at a high level (enable), the buffer 384 outputs, as a pulse signal PFOUT_B, the signal from the inverter 382 to the multiplexer 240. Note that the pulse signals PFOUT_A and PFOUT_B are examples of first and second pulse signals described in the claims.

Furthermore, the detection circuit 311 is divided into a high-voltage domain in which a power supply voltage is VDDH and a low-voltage domain in which a power supply voltage is VDDL lower than VDDH.

In the high-voltage domain, a PR current source 321, a PR switch 322, a gating switch 323, a PR pulse generation circuit 324, and a gating circuit 350 are arranged. Moreover, the AR current source 325, the AR switch 326, the AQ switch 327, the AR pulse generation circuit 330, the AQ pulse generation circuit 340, the inverter 381, and a part of the latch signal generation circuit 360 are arranged in the high-voltage domain.

On the other hand, in the low-voltage domain, the rest of the latch signal generation circuit 360, the inverter 382, the buffer 383, the buffer 384, and the output control circuit 370 are arranged.

Note that the circuit configuration of the detection circuit 311 is not limited to that illustrated in the drawing as long as the detection circuit can detect incidence of photons. For example, in a case where the active recharging and the active quenching are not performed, the AR current source 325, the AR switch 326, the AQ switch 327, the AR pulse generation circuit 330, and the AQ pulse generation circuit 340 are unnecessary. Furthermore, in a case where pixels are not selected in units of rows and columns, the latch signal generation circuit 360 becomes unnecessary. Furthermore, in a case where only one system is used for output instead of two systems, the buffer 383, the buffer 384, and the output control circuit 370 are unnecessary. Furthermore, in the case of not being divided into the high-voltage domain and the low-voltage domain, one of the inverters 381 and 382 can be reduced. Furthermore, the detection circuit 311 or the like detects the incidence of photons outside the detection stop period on the basis of the cathode voltage, but can also detect the incidence of photons on the basis of an anode voltage.

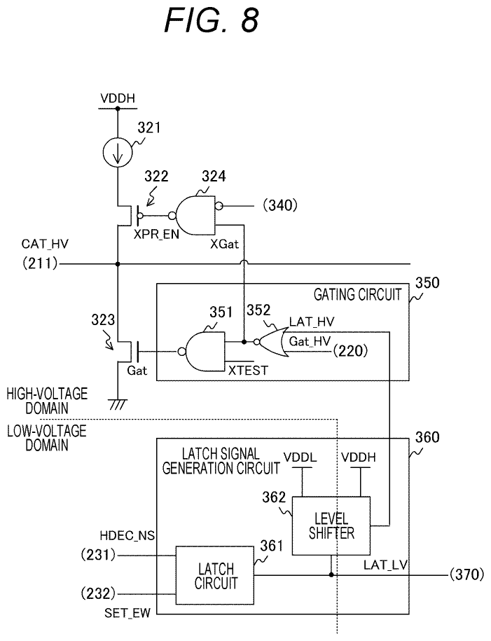

FIG. 8 is a circuit diagram illustrating a configuration example of the gating circuit 350 and the latch signal generation circuit 360 in the first embodiment of the present technology. The gating circuit 350 includes a NAND gate 351 and a NOR (negative OR) gate 352. Furthermore, the latch signal generation circuit 360 includes a latch circuit 361 and a level shifter 362.

The latch circuit 361 latches the decoded signals HDEC_NS and SET_EW from the H decoder 231 and the V decoder 232 to generate a latch signal LAT_LV. The latch signal LAT_LV is supplied to the output control circuit 370 and the level shifter 362 in the low-voltage domain. The H decoder 231 and the V decoder 232 can set whether or not to drive on a pixel basis by the decoded signals HDEC_NS and SET_EW. A high level is set to the latch signal LAT_LV of the pixel to be driven by the decoded signals HDEC_NS and SET_EW.

The level shifter 362 shifts the high level of the latch signal LAT_LV from VDDL to VDDH. The level shifter 362 supplies, as LAT_HV, the shifted latch signal to the NOR gate 352.

The NOR gate 352 obtains a negative OR of the latch signal LAT_HV and the gating pulse Gat_HV. The NOR gate 352 supplies a negative OR signal as XGat to the NAND gate 351 and the PR pulse generation circuit 324.

The NAND gate 351 supplies, as the gating pulse Gat, a negative AND of XGat and a test signal XTEST to the gating switch 323. Here, the test signal XTEST is a signal set by a predetermined test circuit (not illustrated), and is used to forcibly turn on the gating switch 323 when a test related to gating is performed. When the on state is forcibly set, for example, a low level is set to the test signal XTEST.

Furthermore, in the latch signal generation circuit 360, a part of the level shifter 362 and the latch circuit 361 are arranged in the low-voltage domain, and the rest of the level shifter 362 is arranged in the high-voltage domain.

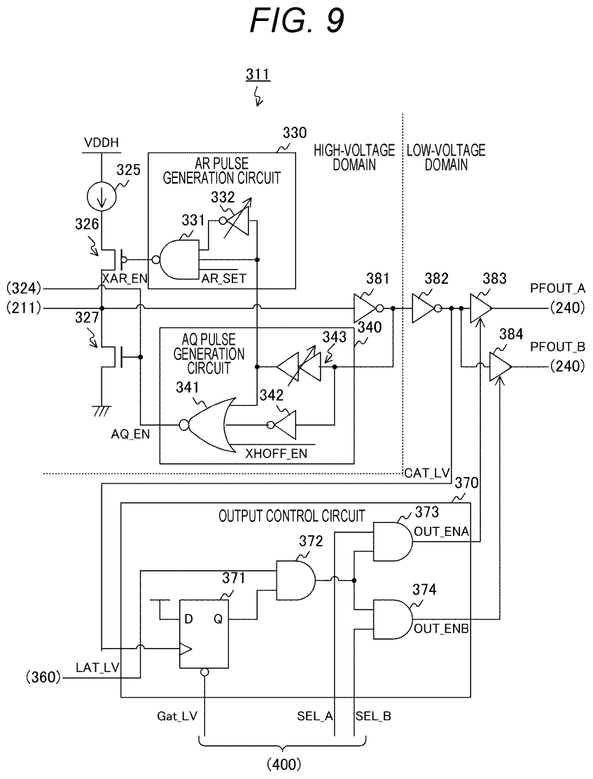

FIG. 9 is a circuit diagram illustrating a configuration example of the AR pulse generation circuit 330, the AQ pulse generation circuit 340, and the output control circuit 370 in the first embodiment of the present technology. The AR pulse generation circuit 330 includes a NAND gate 331 and an inverter 332. The AQ pulse generation circuit 340 includes a NOR gate 341, an inverter 342, and a delay circuit 343. The output control circuit 370 includes a flip-flop 371 and AND gates 372, 373, and 374.

In the output control circuit 370, the flip-flop 371 fetches and holds a high-level signal in synchronization with the signal CAT_LV from the inverter 382. Furthermore, the inverted value of the gating pulse Gat_LV from the shared circuit 400 is input to the enable terminal of the flip-flop 371. In a case where the inverted value is at a high level, the flip-flop 371 supplies the held signal to the AND gate 372.

The AND gate 372 supplies a logical product of the latch signal LAT_LV and the signal from the flip-flop 371 to the AND gates 373 and 374.

The AND gate 373 supplies, as the output enable signal OUT_ENA, a logical product of a selection signal SEL_A from the shared circuit 400 and the signal from the AND gate 372 to the buffer 383.

The AND gate 374 supplies, as the output enable signal OUT_ENB, a logical product of a selection signal SEL_B from the shared circuit 400 and the signal from the AND gate 372 to the buffer 384.

In the AQ pulse generation circuit 340, the delay circuit 343 delays the signal from the inverter 381 over a predetermined period and supplies the delayed signal to the NOR gate 341 and the AR pulse generation circuit 330.

The inverter 342 inverts the signal from the inverter 381 and supplies the inverted signal to the NOR gate 341.

The NOR gate 341 supplies, as the AQ enable signal AQ_EN, a negative OR of the signal from the delay circuit 343, the signal from the inverter 342, and a control signal XHOFF_EN to the AQ switch 327. Here, the control signal XHOFF_EN is a signal for forcibly turning off the AQ switch 327 regardless of the signal from the inverter 381, and is generated by a control circuit (not illustrated) outside the detection circuit 311. For example, when the off state is forcibly set, a high level is set to the control signal XHOFF_EN.

In the AR pulse generation circuit 330, the inverter 332 inverts and delays the signal from the delay circuit 343 and supplies the signal to the NAND gate 331.

The NAND gate 331 supplies, as the AR enable signal XAR_EN, a negative AND of the signal from the inverter 332, the signal from the delay circuit 343, and the control signal AR_SET to the AR switch 326. Here, the control signal AR_SET is a signal for forcibly turning off the AR switch 326 regardless of the signal from the AQ pulse generation circuit 340, and is generated by a control circuit (not illustrated) outside the detection circuit 311. For example, when the on state is forcibly set, a low level is set to the control signal AR_SET.

With the circuit configuration illustrated in the drawing, the AQ pulse generation circuit 340 turns on the AQ switch 327 for a certain period after the cathode voltage drops due to the incidence of the ToF light and forcibly sets the cathode voltage to 0 volt. This period is referred to as an “active quench period”. Furthermore, the AR pulse generation circuit 330 turns on the AR switch 326 for a certain period of time after the active quench period has elapsed and supplies the recharge current. That is, the active recharge is started when the active quench period has elapsed.

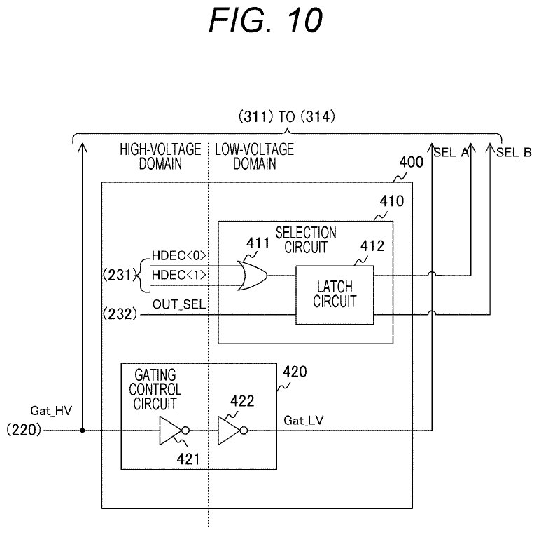

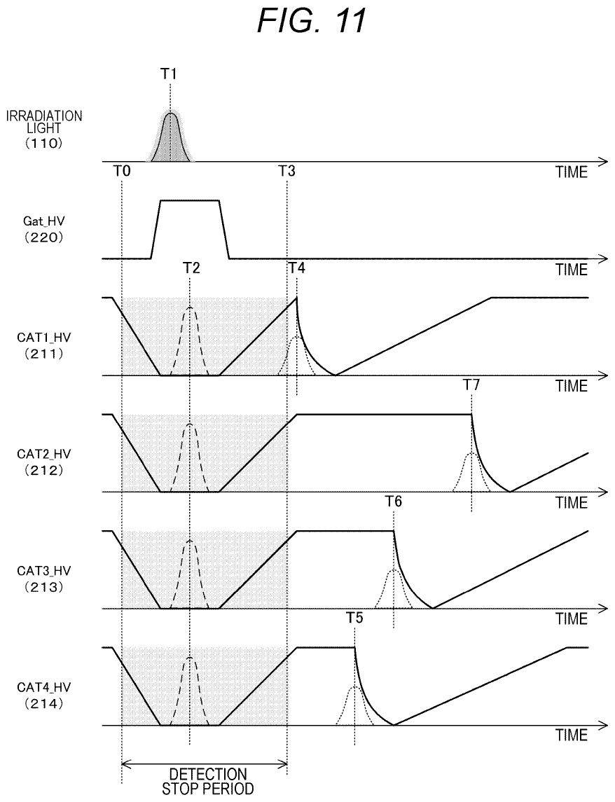

FIG. 10 is a circuit diagram illustrating a configuration example of the shared circuit 400 in the first embodiment of the present technology. The shared circuit 400 includes a selection circuit 410 and a gating control circuit 420.

The selection circuit 410 generates a selection signal indicating one of pulse signals PFOUTA and PFOUTB, and supplies the selection signal to each of the detection circuits 311 to 314. The selection circuit 410 includes an OR (logical sum) gate 411 and a latch circuit 412.

The OR gate 411 obtains a logical sum of the decoded signals HDEC<0> and HDEC<1> from the H decoder 231, and outputs the logical sum to the latch circuit 412.

The latch circuit 412 generates the selection signals SEL_A and SEL_B on the basis of the signal from the OR gate 411 and the decoded signal OUT_SEL from the V decoder 232. For example, an SR latch circuit is used as the latch circuit 412.

The H decoder 231 and the V decoder 232 can set the selection signal by the decoded signals HDEC<0>, HDEC<1>, and OUT_SEL and output both or one of the pulse signals PFOUTA and PFOUTB. In a case where the pulse signal PFOUTA is output, a high level is set to the selection signal SEL_A by the decoded signal, and the low level is set to the selection signal SEL_B. In a case where the pulse signal PFOUTB is output, a low level is set to the selection signal SEL_A by the decoded signal, and a high level is set to the selection signal SEL_B. In a case where both the pulse signals PFOUTA and PFOUTB are output, a high level is set to both the selection signals SEL_A and SEL_B.

The gating control circuit 420 controls the high level of the gating pulse Gat_HV from the power supply voltage VDDH to the power supply voltage VDDL and supplies the gating pulse to each of the detection circuits 311 to 314. The gating control circuit 420 includes inverters 421 and 422. The inverter 421 is arranged in the high-voltage domain, and the inverter 422 and the selection circuit 410 are arranged in the low-voltage domain.

The inverter 421 inverts the gating pulse Gat_HV and supplies the inverted gating pulse Gat_HV to the inverter 422. The inverter 422 inverts the signal from the inverter 422 and supplies the inverted signal as the gating pulse Gat_LV to each of the detection circuits 311 to 314. Note that the inverter 421 is an example of a pre-stage inverter described in the claims, and the inverter 422 is an example of a post-stage inverter described in the claims.

As described above, the gating control circuit 420 controls the voltage of the gating pulse Gat_HV. Each of the detection circuits 311 to 314 detects the incidence of photons within a period not corresponding to the detection stop period indicated by the gating pulse, and generates the pulse signals PFOUTA and PFOUTB. Furthermore, the selection circuit 410 also generates the selection signals SEL_A and SEL_B. Each of the detection circuits 311 to 314 outputs either the pulse signal PFOUTA or PFOUTB according to the selection signal.

Note that the detection circuit 311 is an example of a first detection circuit described in the claims, and the detection circuit 312 is an example of a second detection circuit described in the claims.

### Pixel Operation Example

FIG. 11 is a timing chart illustrating an example of an operation of the pixel in the first embodiment of the present technology. The cathode voltages of the four pixels sharing the shared circuit 400 are CAT1_HV, CAT2_HV, CAT3_HV, and CAT4_HV, respectively.

It is assumed that the light emitting unit 110 emits irradiation light at timing T1. At timing T2 immediately after that, stray light is generated and incident on each pixel. A waveform of a rough dotted line in the drawing indicates a waveform of the stray light.

The timing generation unit 220 generates the gating pulse Gat_HV that becomes a high level over a certain period including timing T1. By the gating pulse Gat_HV, the cathode voltage of each pixel is controlled to a low level equal to or lower than the threshold of the first-stage inverter 381 over the period from timing T0 to timing T3. This period corresponds to a detection stop period during which the incidence of photons cannot be detected.

Then, the ToF light is incident on each pixel at timings T4, T5, T6, and T7 after the detection stop period has elapsed. A waveform of a fine dotted line in the drawing indicates the irradiation intensity of the ToF light. Since the detection stop period has elapsed, each of the pixels detects the incidence of the ToF light, and the cathode voltage drops.

In a configuration in which the gating is not performed, each pixel detects the incidence of stray light at timing T2, and the incidence of new photons cannot be detected until the dead time has elapsed. Therefore, for example, the pixel cannot detect the incidence of the ToF light at timing T4, and the distance measurement performance for a short distance is deteriorated. On the other hand, since the photodetection element 200 performs the gating, it is possible to detect the incidence of the ToF light at timing T4 or the like as illustrated in the drawing, and it is possible to improve the distance measuring performance in a short distance.

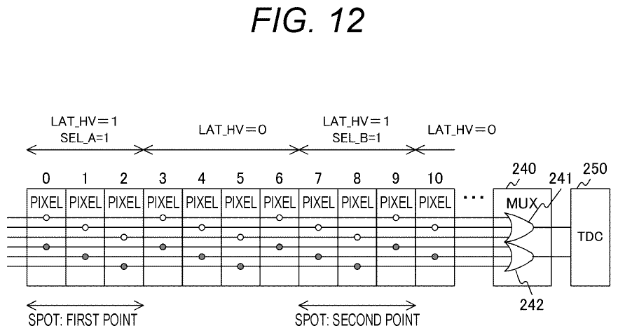

FIG. 12 is a diagram for describing an example of control of the decoder in the first embodiment of the present technology. Attention is focused on pixels from the 0th column to the 10th column in a certain row. In the drawing, a white circle indicates the output terminal of the pulse signal of the A system, and a black circle indicates the output terminal of the pulse signal of the B system. Furthermore, OR gates 241 and 242 are arranged for each row in the multiplexer 240.

The OR gate 241 supplies the logical sum of the A-system pulse signals of the 3K (K is an integer of 0 or more) column, the 3K+1 column, and the 3K+2 column to the TDC 250. The OR gate 242 supplies the logical sum of the B-system pulse signals of the 3K column, the 3K+1 column, and the 3K+2 column to the TDC 250.

The H decoder 231 and the V decoder 232 can set whether or not to drive for each pixel and set one of the A system and the B system, based on the decoded signal described above. Therefore, the photodetection element 200 can simultaneously detect the ToF light at two points. For example, it is assumed that the light at the first point is incident from the 0th column to the 2nd column and the light at the second point is incident from the 7th column to the 9th column.

In this case, the H decoder 231 and the V decoder 232 drive by setting the latch signals LAT_HV of the 0th column to the 2nd column and the 7th column to the 9th column to a high level, and set the latch signals of the other columns to a low level. Furthermore, the H decoder 231 and the V decoder 232 set the selection signals SEL_A of the 0th column to 2nd column to a high level, and set the selection signals SEL_B of the 7th column to 9th column to a high level. Therefore, one of the two points can be detected and output in the A system from the 0th column to the 2nd column, and the other of the two points can be detected and output in the B system from the 7th column to the 9th column. Then, a subsequent-stage circuit (TDC or the like) can simultaneously perform distance measurement for each of the two points.

Here, a configuration in which a plurality of pixels does not share the shared circuit 400 is assumed as a first comparative example.

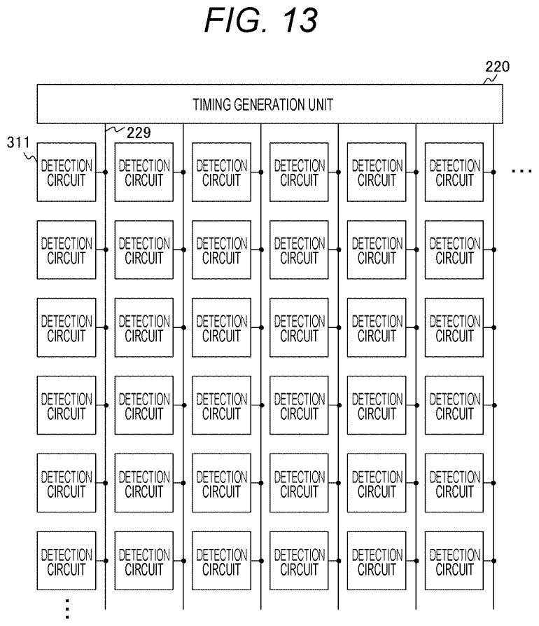

FIG. 13 is a diagram illustrating a wiring example of a signal line for transmitting a gating pulse in the first comparative example. As illustrated in the drawing, in the first comparative example, it is necessary to wire the signal line 229 for transmitting the gating pulse for each column of the detection circuit.

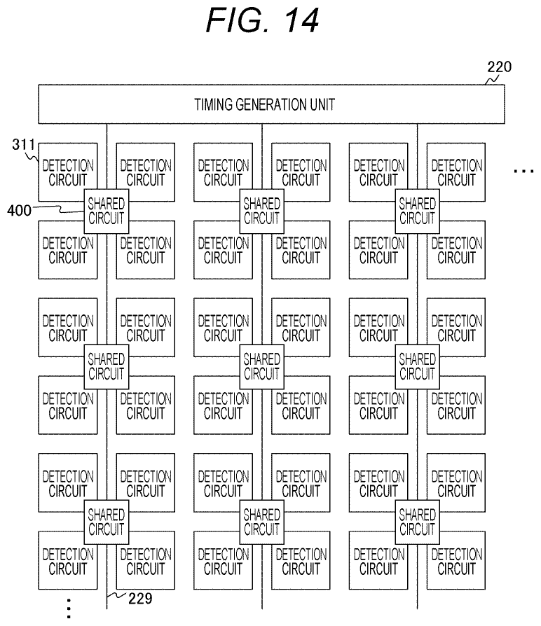

FIG. 14 is a diagram illustrating a wiring example of a signal line 229 for transmitting a gating pulse in the first embodiment of the present technology. Since four pixels of 2 rows×2 columns share the shared circuit 400, the signal lines 229 are wired every two columns.

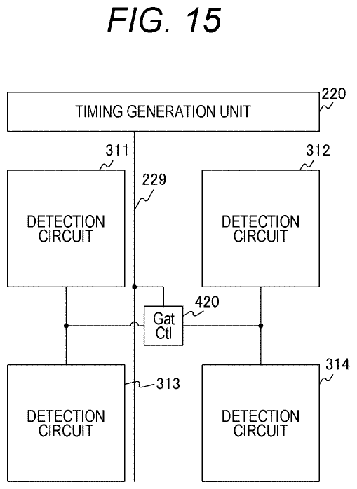

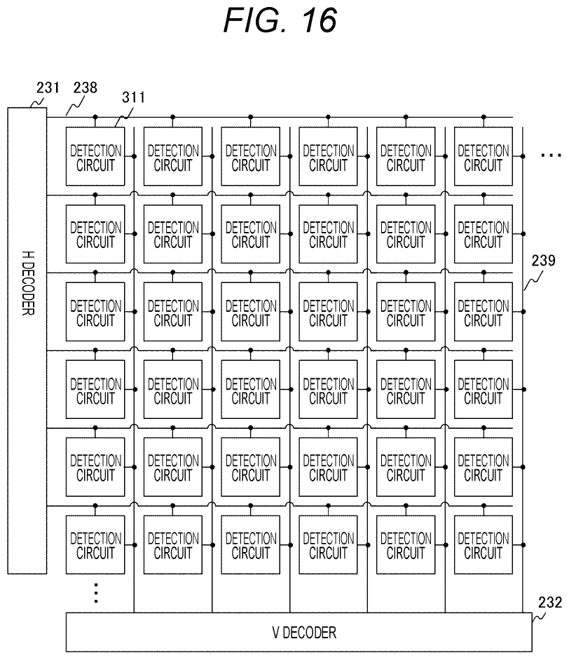

FIG. 15 is a diagram illustrating a wiring example of a signal line for transmitting a gating pulse in a shared block in the first embodiment of the present technology. In the shared block of 2 rows×2 columns, signal lines are wired from the gating control circuit 420 in the shared circuit 400 to the detection circuits 311 to 314. Furthermore, wiring is performed from the gating control circuit 420 at the center to each of the four detection circuits so that wiring lengths are substantially the same.

FIG. 16 is a diagram illustrating a wiring example of signal lines 238 and 239 for transmitting a decoded signal in the first comparative example. As illustrated in the drawing, in the first comparative example, it is necessary to wire the signal line 238 for transmitting the decoded signal from the H decoder 231 for each row and wire the signal line 239 for transmitting the decoded signal from the V decoder 232 for each column. The signal line 238 transmits the decoded signals HDEC<0> and HDEC<1> illustrated in FIG. 10, and the signal line 239 transmits the decoded signal OUT_SEL. The signal line 238 physically includes two wirings, but is represented by one line for convenience of description.

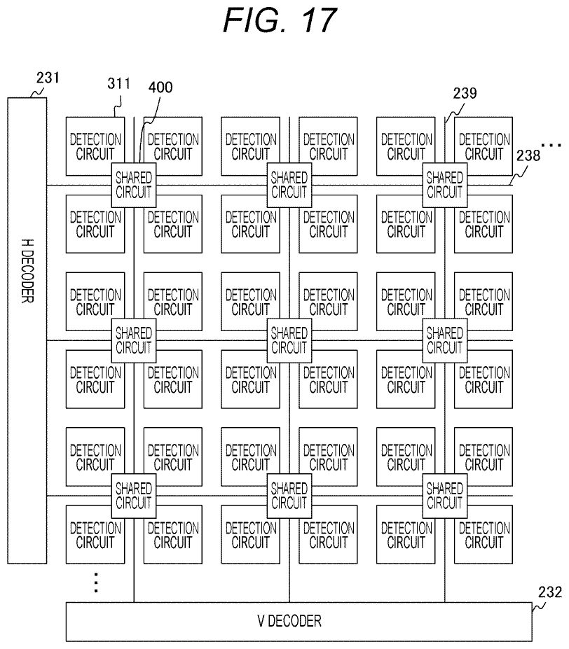

FIG. 17 is a diagram illustrating a wiring example of the signal lines 238 and 239 for transmitting a decoded signal in the first embodiment of the present technology. Since four pixels of 2 rows×2 columns share the shared circuit 400, the signal lines 238 are wired every two rows, and the signal lines 239 are wired every two columns.

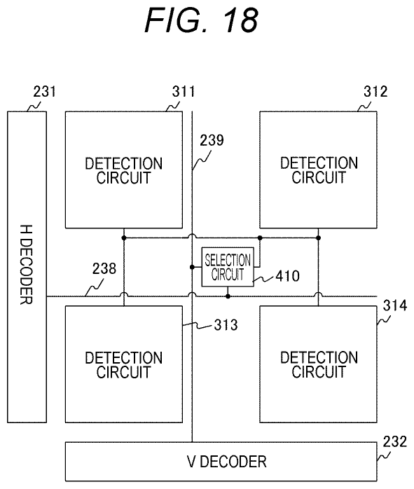

FIG. 18 is a diagram illustrating a wiring example of a signal line for transmitting a decoded signal in a shared block in the first embodiment of the present technology. In the shared block of 2 rows×2 columns, signal lines are wired from the selection circuit 410 in the shared circuit 400 to each of the detection circuits 311 to 314.

As illustrated in FIGS. 13 to 18, the plurality of pixels shares the shared circuit 400, so that the number of wirings of the signal line for transmitting the gating pulse or the decoded signal can be reduced as compared with the first comparative example.

Note that, in the photodetection element 200 described above, four pixels share the shared circuit 400, but the number of pixels sharing the shared circuit 400 is not limited to four, and may be two, sixteen, or the like.

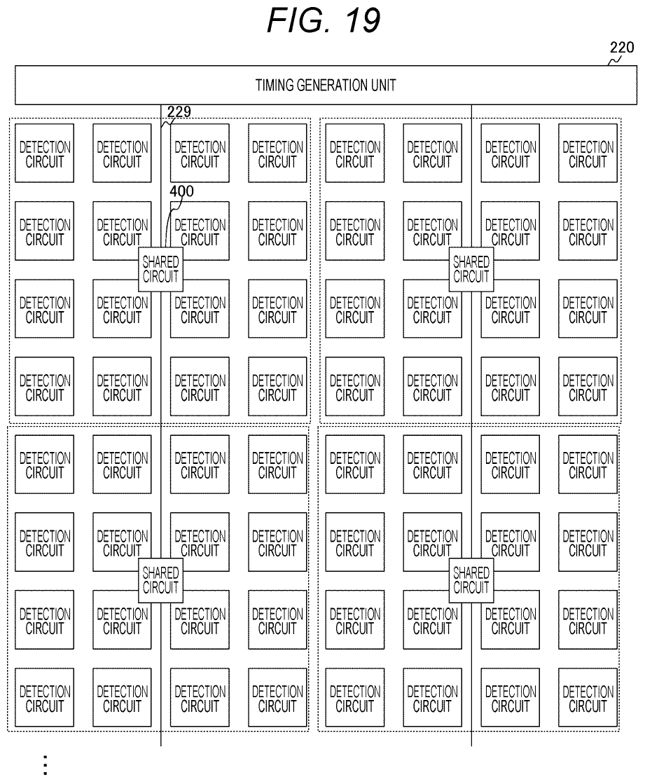

FIG. 19 is a diagram illustrating a wiring example of a signal line for transmitting a gating pulse when the shared circuit 400 is shared by 16 pixels in the first embodiment of the present technology. In the drawing, 4 rows×4 columns surrounded by dotted lines indicate a shared block.

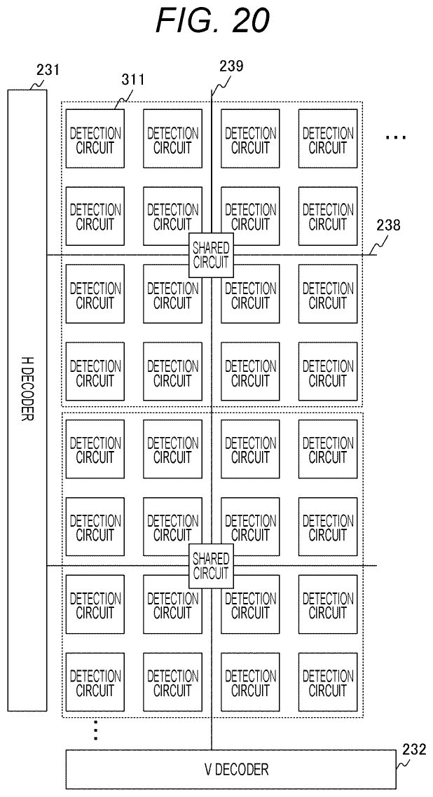

FIG. 20 is a diagram illustrating a wiring example of a signal line for transmitting a decoded signal when the shared circuit 400 is shared by 16 pixels in the first embodiment of the present technology. In the drawing, 4 rows×4 columns surrounded by dotted lines indicate a shared block.

As illustrated in FIGS. 19 and 20, as the number of sharing pixels increases, the number of wirings can be more reduced.

As described above, according to the first embodiment of the present technology, since a plurality of pixels shares the shared circuit 400, a circuit area per pixel can be reduced.

### First Modification

In the first embodiment described above, both the gating control circuit 420 and the selection circuit 410 are shared by four pixels, but one of them may not be shared and may be arranged for each pixel. The photodetection element 200 in a first modification of the first embodiment is different from that of the first embodiment in that the selection circuit 410 is arranged for each pixel.

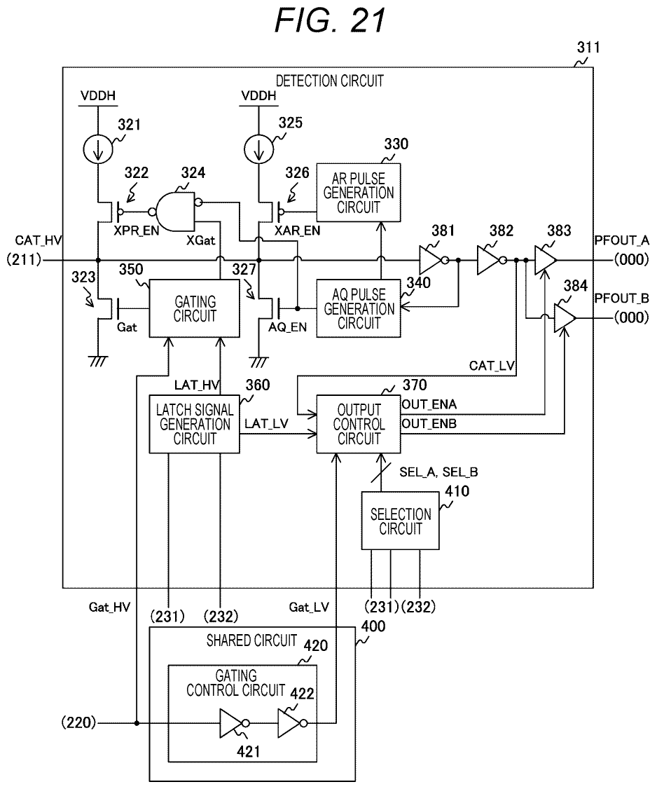

FIG. 21 is a circuit diagram illustrating a configuration example of the detection circuit 311 and the shared circuit 400 in the first modification of the first embodiment of the present technology. In the first modification of the first embodiment, the selection circuit 410 is not arranged in the shared circuit 400, and the selection circuit 410 is arranged in the detection circuit 311. The selection circuit 410 is also arranged in each of the detection circuits 312, 313, and 314.

As described above, according to the first modification of the first embodiment of the present technology, since the selection circuit 410 is arranged in the detection circuit, it is possible to reduce the number of circuits in the shared circuit 400.

### Second Modification

In the first embodiment described above, the gating control circuit 420 including the inverters 421 and 422 is shared by four pixels, but in this configuration, it is difficult to further reduce the circuit area for each pixel. The photodetection element 200 in a second modification of the first embodiment is different from that of the first embodiment in that a logic gate and a flip-flop are arranged in the gating control circuit 420.

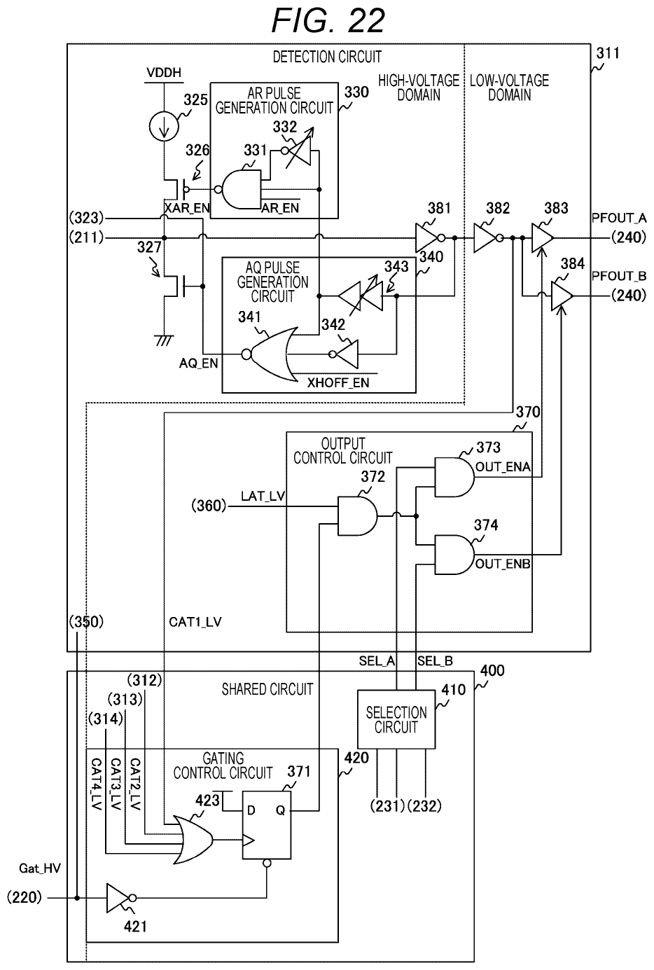

FIG. 22 is a circuit diagram illustrating a configuration example of the detection circuit 311 and the shared circuit 400 in the second modification of the first embodiment of the present technology. The shared circuit 400 of the second modification of the first embodiment is different from that of the first embodiment in that the OR gate 423 and the flip-flop 371 are arranged in the gating control circuit 420 instead of the inverter 422. Furthermore, the flip-flop 371 is not arranged in the detection circuit 311.

The last-stage inverter 382 in the detection circuit 311 outputs the inverted signal as CAT1_LV to the OR gate 423. The last-stage inverter in the detection circuit 312 outputs CAT2_LV to the OR gate 423, and the last-stage inverter in the detection circuit 313 outputs CAT3_LV to the OR gate 423. The last-stage inverter in the detection circuit 314 outputs CAT4_LV to the OR gate 423.

The OR gate 423 supplies a logical sum of CAT1_LV, CAT2_LV, CAT3_LV, and CAT4_LV to a clock terminal of the flip-flop 371.

Furthermore, the inverter 421, the OR gate 423, and the flip-flop 371 are arranged in the low-voltage domain.

As illustrated in the drawing, by arranging the flip-flop 371 in the shared circuit 400, the flip-flop 371 can be reduced in each of the detection circuits 311 to 314.

As described above, according to the second modification of the first embodiment of the present technology, since the flip-flop 371 is arranged in the shared circuit 400, it is possible to reduce the number of flip-flops in the detection circuit 311 and the like.

### 2. Second Embodiment

In the first embodiment described above, the AR pulse generation circuit 330 starts the active recharging when the active quench period has elapsed, but with this configuration, it is difficult to further shorten the dead time. The photodetection element 200 in the second embodiment is different from that in the first embodiment in that the active recharging is started even when the detection stop period has elapsed.

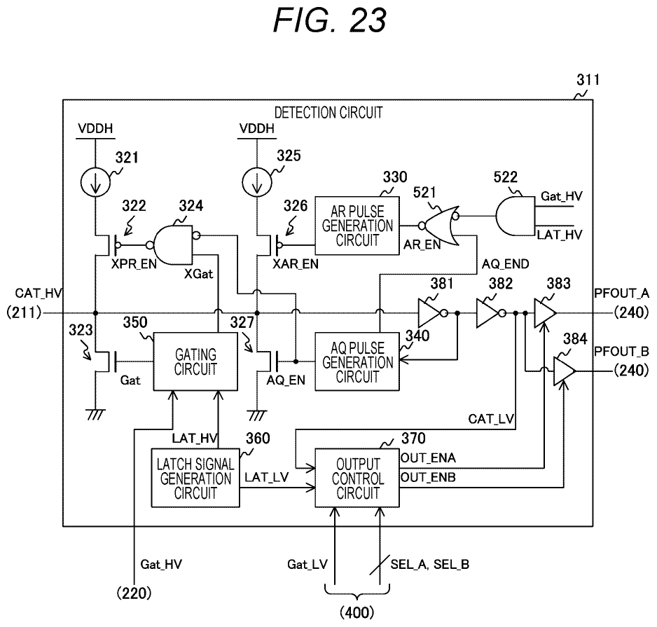

FIG. 23 is a block diagram illustrating a configuration example of the detection circuit 311 in the second embodiment of the present technology. The detection circuit 311 of the second embodiment is different from that in the first embodiment in further including a NOR gate 521 and an AND gate 522.

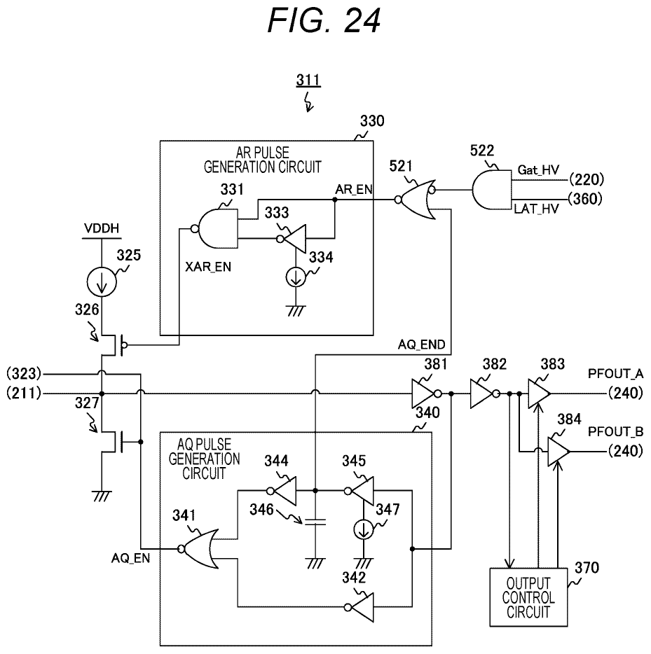

FIG. 24 is a circuit diagram illustrating a configuration example of the AR pulse generation circuit 330 and the AQ pulse generation circuit 340 in the second embodiment of the present technology.

The AQ pulse generation circuit 340 of the second embodiment implements the function of the delay circuit 343 by inverters 344 and 345, a capacitive element 346, and a current source 347. Furthermore, the AR pulse generation circuit 330 of the second embodiment includes an inverter 333 and a current source 334 instead of the inverter 332.

The inverter 345 inverts a signal from the inverter 381 and supplies the inverted signal as the AQ end signal AQ_END to the inverter 344 and the NOR gate 521. The current source 347 is connected to a ground terminal of the inverter 345. The capacitive element 346 is connected to a connection node of the inverters 344 and 345. The inverter 344 inverts the AQ end signal AQ_END and supplies the inverted AQ end signal AQ_END to the NOR gate 341.

The AND gate 522 supplies a logical product of the gating pulse Gat_HV and the latch signal LAT_HV to the NOR gate 521.

The NOR gate 521 supplies, as the AR_EN, a negative OR of the inverted value of the signal from the AND gate 522 and the AQ end signal AQ_END to the NAND gate 331 and the inverter 333.

The inverter 333 inverts the AR_EN from the NOR gate 521 and supplies the inverted AR_EN to the NAND gate 331. The current source 334 is connected to a ground terminal of the inverter 333.

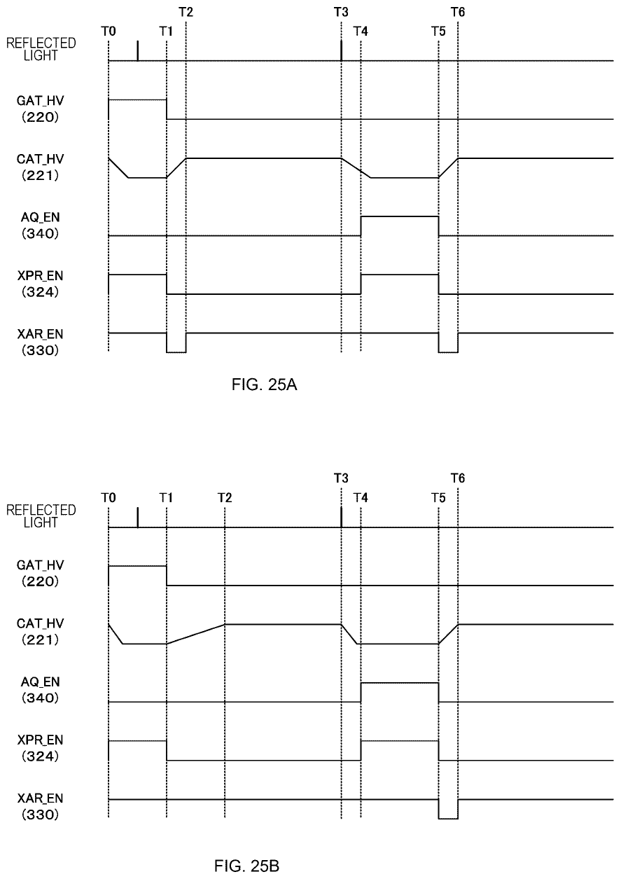

FIG. 25 is an example of a timing chart illustrating each of active recharge control in the second embodiment of the present technology and active recharge control in the first embodiment. In the drawing, a indicates control of the active recharge in the second embodiment, and b indicates control of the active recharge in the first embodiment.

In a of the drawing, it is assumed that stray light that is reflected light in the distance measuring module 100 is generated during the detection stop period from timing T0 to timing T1. In order to prevent the SPAD reaction due to stray light, the high-level gating pulse Gat_HV is supplied over the period.

The AR pulse generation circuit 330 generates the low-level AR enable signal XAR_EN within a period from timing T1 to timing T2 in which the gating is ended (that is, the detection stop period has elapsed). The cathode is rapidly charged by the active recharging after the gating.

Then, it is assumed that ToF light that is reflected light reflected by the target is incident at timing T3 after timing T2. The cathode voltage CAT_HV drops, and the SPAD reaction triggers the AQ pulse generation circuit 340 to generate a high-level AQ enable signal over an active quench period from timing T4 to timing T5.

Furthermore, the AR pulse generation circuit 330 generates the low-level AR enable signal XAR_EN in the period from timing T5 to timing T6 after the active quench period has elapsed. This active recharging rapidly charges the cathode.

The control in a of the drawing is realized by the circuit configuration illustrated in FIG. 24.

On the other hand, as illustrated in b of FIG. 25, in the first embodiment, the AR enable signal XAR_EN remains at a high level in the period from timing T1 to timing T2 after the detection stop period has elapsed, and the active recharging is not executed. Therefore, the dead time becomes long due to low-speed charging. Furthermore, the active recharging after the active quench period has elapsed is executed similarly to the second embodiment.

As described above, in the second embodiment, the AR pulse generation circuit 330 generates the low-level AR enable signal and performs active recharge when the detection stop period has elapsed or when the active quench period has elapsed. In particular, by performing active recharging even when the detection stop period has elapsed, the dead time can be shortened as compared with the first embodiment.

As described above, according to the second embodiment of the present technology, the AR pulse generation circuit 330 generates the low-level AR enable signal when the detection stop period has elapsed or when the active quench period has elapsed, so that the dead time can be shortened.

### 3. Third Embodiment

In the first embodiment described above, the gating control circuit 420 and the selection circuit 410 are shared by a plurality of pixels, but with this configuration, it is difficult to further reduce the circuit area per pixel. The photodetection element 200 in the third embodiment is different from that of the first embodiment in that a plurality of pixels further shares a recharge circuit, the AQ pulse generation circuit 340, and the like.

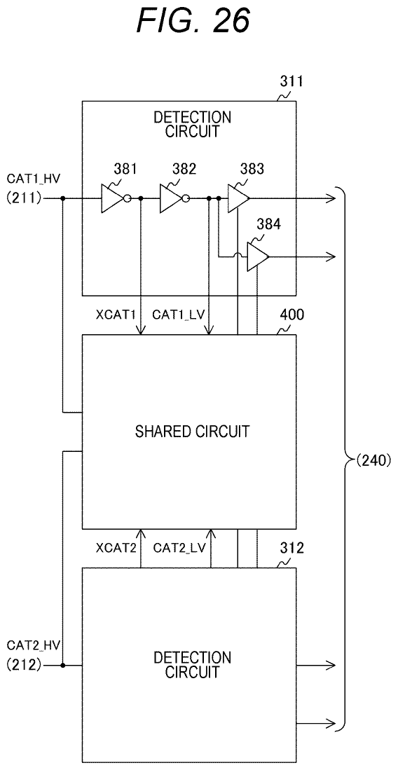

FIG. 26 is a circuit diagram illustrating a configuration example of the detection circuit 311 in the third embodiment of the present technology. In the third embodiment, it is assumed that the shared circuit 400 is shared by two pixels.

The detection circuit 311 includes inverters 381 and 382 and buffers 383 and 384. The circuit configuration of the detection circuit 312 is similar to that of the detection circuit 311.

Furthermore, the inverter 381 in the detection circuit 311 supplies the inverted signal XCAT1 to the shared circuit 400, and the inverter 382 supplies the pulse signal CAT1_LV to the shared circuit 400. A first-stage inverter (not illustrated) in the detection circuit 312 supplies the inverted signal XCAT2 to the shared circuit 400, and a subsequent-stage inverter (not illustrated) supplies the pulse signal CAT2_LV to the shared circuit 400.

Note that the number of sharing pixels is not limited to two, and may be four or the like.

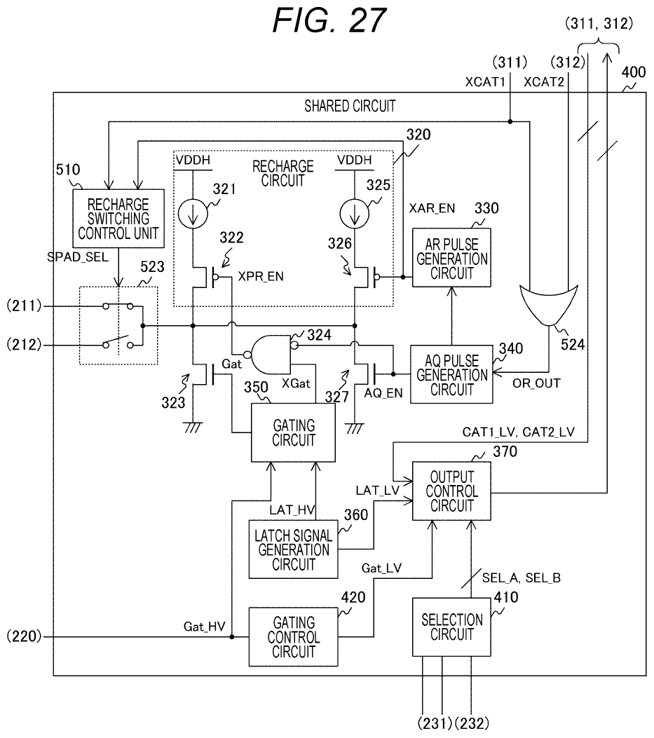

FIG. 27 is a block diagram illustrating a configuration example of the shared circuit 400 in the third embodiment of the present technology. The shared circuit 400 of the third embodiment further includes the PR current source 321, the PR switch 322, the gating switch 323, the PR pulse generation circuit 324, the gating circuit 350, and the latch signal generation circuit 360 in addition to the gating control circuit 420 and the selection circuit 410. Furthermore, the detection circuit 311 includes the AR current source 325, the AR switch 326, the AQ switch 327, the AR pulse generation circuit 330, and the AQ pulse generation circuit 340. Moreover, the detection circuit 311 includes the output control circuit 370, a recharge switching control unit 510, a recharge switching switch 523, and an OR gate 524.

Furthermore, in the third embodiment, a circuit including the PR current source 321, the PR switch 322, the AR current source 325, and the AR switch 326 is referred to as a recharge circuit 320.

A recharge switching switch 523 selects one of the cathode of the photoelectric conversion element 211 or the cathode of the photoelectric conversion element 212 according to a switching signal SPAD_SEL, and is connected to the recharge circuit 320.

A recharge switching control unit 510 generates the switching signal SPAD_SEL on the basis of the inverted signal XCAT1 and the AR enable signal XAR_EN, and supplies the switching signal SPAD_SEL to the recharge switching switch 523.

The OR gate 524 supplies, as the OR_OUT, a logical sum of the inverted signals XCAT1 and XCAT2 to the AQ pulse generation circuit 340.

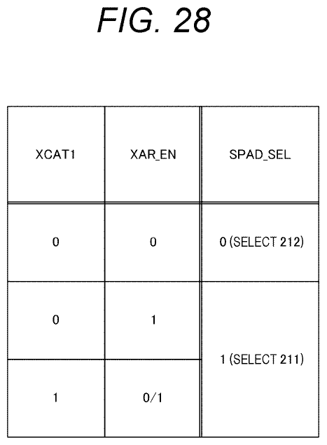

FIG. 28 is a diagram illustrating an example of an operation of the recharge switching control unit 510 in the third embodiment of the present technology.

In a case where the inverted signal XCAT1 is a logical value “0” and the AR enable signal XAR_EN is a logical value “0”, the recharge switching control unit 510 selects the photoelectric conversion element 212 and generates SPAD_SEL of a logical value “0”.

In a case where the inverted signal XCAT1 is a logical value “0” and the AR enable signal XAR_EN is a logical value “1”, the recharge switching control unit 510 selects the photoelectric conversion element 211 and generates SPAD_SEL of a logical value “1”.

In a case where the inverted signal XCAT1 is a logical value “1”, the recharge switching control unit 510 selects the photoelectric conversion element 211 and generates SPAD_SEL of a logical value “1”.

Here, a configuration in which the recharge circuit 320 is provided for each pixel without being shared, and the PR pulse generation circuit 324 and the AR pulse generation circuit 330 are shared by a plurality of pixels is assumed as a second comparative example. The circuit of the second comparative example is described in FIG. 5 of Japanese Patent Application Laid-Open No. 2019-158806 and the like. The PR pulse generation circuit 324 and the AR pulse generation circuit 330 are arranged in the recharge signal generation circuit in the drawing. Note that, in a case where the active recharging is not performed, the AR pulse generation circuit 330 is not arranged in the recharge signal generation circuit.

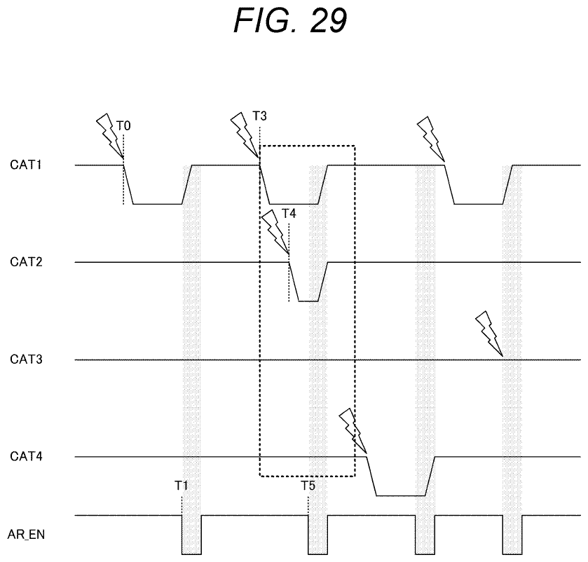

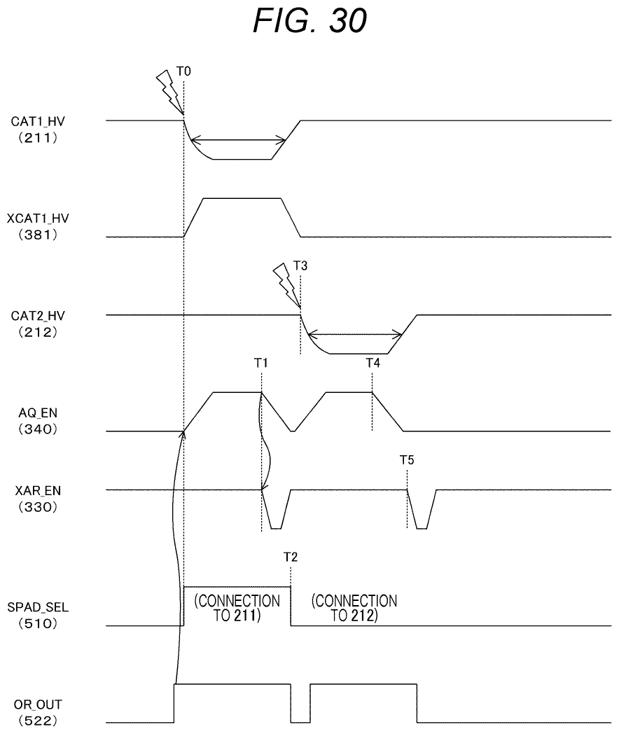

FIG. 29 is a timing chart illustrating an example of an operation of the detection circuit in the second comparative example. When photons are incident on the first pixel corresponding to the cathode voltage CAT1 at timing T0, all the four pixels in the shared block are charged by active recharging within a certain period from timing T1. Furthermore, it is assumed that photons are incident on the first pixel at timing T3, and the photons are incident on the second pixel corresponding to the cathode voltage CAT2 at timing T4 immediately after that. As described above, in a case where photons are incident on two pixels almost simultaneously, the photodetection element 200 cannot detect the incidence of photons on the second pixel. Then, all the four pixels are charged by active recharging within a certain period from timing T5. Thereafter, similarly, every time photons are incident on any of the four pixels, all of the four pixels are charged.

As illustrated in the drawing, in the second comparative example, every time photons are incident on any of the four pixels, the four pixels are charged simultaneously, and thus instantaneous power consumption increases as compared with the case of charging one pixel at a time. Furthermore, in a case where photons are incident on two pixels almost simultaneously, the photodetection element 200 cannot detect the incidence of photons of one pixel.

FIG. 30 is a timing chart illustrating an example of an operation of the shared circuit 400 in a case where photons are incident on each pixel in sequence in the third embodiment of the present technology. It is assumed that photons are incident on the first pixel corresponding to the cathode voltage CAT1_HV at timing T0. The recharge switching control unit 510 connects the photoelectric conversion element 211 to the recharge circuit 320 by the high-level switching signal SPAD_SEL. According to the rise of the output OR_OUT of the OR gate 524, the AQ pulse generation circuit 340 generates the high-level AQ enable signal AQ_EN over a certain period. Therefore, the active quenching is performed.

Then, when the AQ enable signal AQ_EN falls at timing T1, the AR pulse generation circuit 330 generates the low-level AR enable signal XAR_EN over a certain period. Since the photoelectric conversion element 211 is connected to the recharge circuit 320, only the first pixel is charged by active recharging. At timing T2 immediately after that, the recharge switching control unit 510 connects the photoelectric conversion element 212 to the recharge circuit 320 by the low-level switching signal SPAD_SEL.

Subsequently, it is assumed that photons are incident on the second pixel corresponding to the cathode voltage CAT2_HV at timing T3. The AQ pulse generation circuit 340 generates the high-level AQ enable signal AQ_EN over a certain period.

Then, when the AQ enable signal AQ_EN falls at timing T4, the AR pulse generation circuit 330 generates the low-level AR enable signal XAR_EN over a certain period from timing T5. Since the photoelectric conversion element 212 is connected to the recharge circuit 320, only the second pixel is charged by active recharging.

As illustrated in the drawing, since the recharge switching control unit 510 switches the connection destination of the recharge circuit 320, in a case where photons are incident on one of the two pixels, only the pixel is charged.

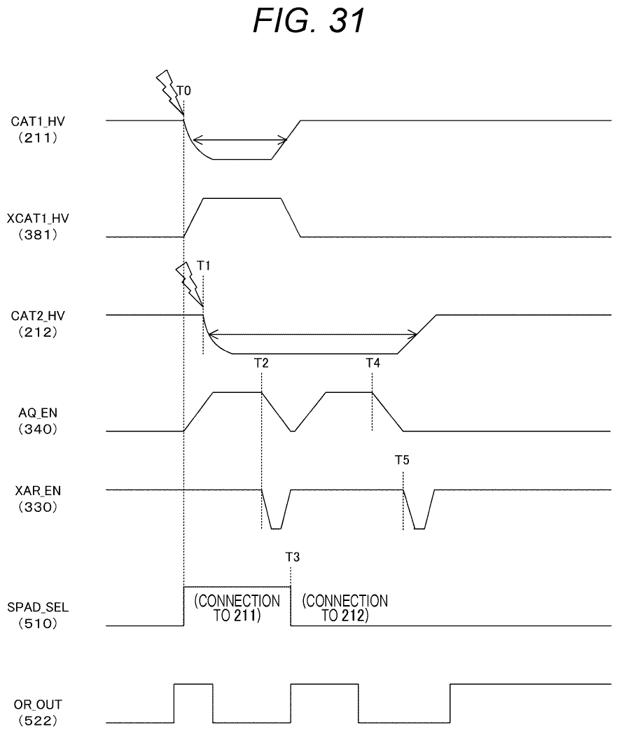

FIG. 31 is a timing chart illustrating an example of an operation of the shared circuit 400 in a case where photons are incident on two pixels almost simultaneously in the third embodiment of the present technology. It is assumed that photons are incident on the first pixel at timing T0, and photons are incident on the second pixel at timing T1 immediately after that. The recharge switching control unit 510 connects the photoelectric conversion element 211 to the recharge circuit 320 by the high-level switching signal SPAD_SEL. Furthermore, the AQ pulse generation circuit 340 generates the high-level AQ enable signal AQ_EN over a certain period.

Then, when the AQ enable signal AQ_EN falls at timing T2, the AR pulse generation circuit 330 generates the low-level AR enable signal XAR_EN over a certain period. Since the photoelectric conversion element 211 is connected to the recharge circuit 320, only the first pixel is charged by active recharging. At timing T3 immediately after that, the recharge switching control unit 510 connects the photoelectric conversion element 212 to the recharge circuit 320 by the low-level switching signal SPAD_SEL. Furthermore, the AQ pulse generation circuit 340 generates the high-level AQ enable signal AQ_EN over a certain period.

Then, when the AQ enable signal AQ_EN falls at timing T4, the AR pulse generation circuit 330 generates the low-level AR enable signal XAR_EN over a certain period from timing T5. Since the photoelectric conversion element 212 is connected to the recharge circuit 320, only the second pixel is charged by active recharging.

As illustrated in the drawing, even in a case where photons are incident on two pixels almost simultaneously, the recharge switching control unit 510 switches the connection destination at the time of completing the active recharging for one pixel, so that charging can be performed sequentially pixel by pixel.

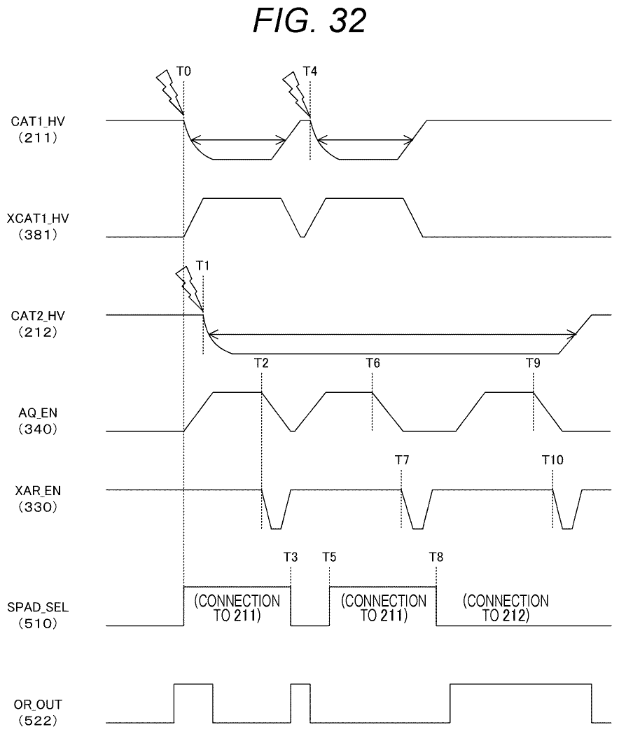

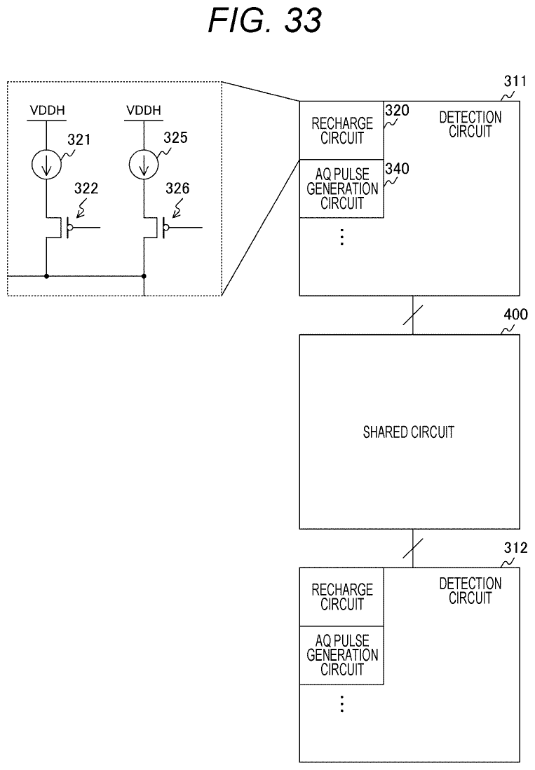

FIG. 32 is a timing chart illustrating an example of an operation of the shared circuit 400 in a case where photons are incident on two pixels almost simultaneously and then photons are incident on one pixel in the third embodiment of the present technology.

It is assumed that photons are incident on the first pixel at timing T0, and photons are incident on the second pixel at timing T1 immediately after that. The recharge switching control unit 510 connects the photoelectric conversion element 211 to the recharge circuit 320 by the high-level switching signal SPAD_SEL. Furthermore, the AQ pulse generation circuit 340 generates the high-level AQ enable signal AQ_EN over a certain period.

Then, when the AQ enable signal AQ_EN falls at timing T2, the AR pulse generation circuit 330 generates the low-level AR enable signal XAR_EN over a certain period. Since the photoelectric conversion element 211 is connected to the recharge circuit 320, only the first pixel is charged by active recharging. At timing T3 immediately after that, the recharge switching control unit 510 connects the photoelectric conversion element 212 to the recharge circuit 320 by the low-level switching signal SPAD_SEL.

Then, it is assumed that photons are further incident on the first pixel at timing T4. At timing T5, the recharge switching control unit 510 connects the photoelectric conversion element 211 to the recharge circuit 320 by the high-level switching signal SPAD_SEL.

When the AQ enable signal AQ_EN falls at timing T6, the AR pulse generation circuit 330 generates the low-level AR enable signal XAR_EN over a certain period from timing T7. Since the photoelectric conversion element 211 is connected to the recharge circuit 320, only the first pixel is charged by active recharging.

At timing T8 when the active recharge is completed, the recharge switching control unit 510 connects the photoelectric conversion element 212 to the recharge circuit 320 by the low-level switching signal SPAD_SEL. Furthermore, the AQ pulse generation circuit 340 generates the high-level AQ enable signal AQ_EN over a certain period.

Then, when the AQ enable signal AQ_EN falls at timing T9, the AR pulse generation circuit 330 generates the low-level AR enable signal XAR_EN over a certain period from timing T10. Since the photoelectric conversion element 212 is connected to the recharge circuit 320, only the second pixel is charged by active recharging.

As illustrated in the drawing, even in a case where photons are incident on two pixels almost simultaneously and photons are incident on one pixel before completion of recharging for two pixels, the shared circuit 400 can preferentially recharge one cathode and recharge the other cathode after completion of recharging.

As illustrated in FIGS. 30, 31, and 32, since the recharge switching control unit 510 switches the connection destination of the recharge circuit 320, charging can be performed sequentially pixel by pixel. Therefore, instantaneous power consumption can be reduced as compared with the second comparative example in which four pixels are simultaneously charged. Furthermore, since the connection destination of the active recharge is switched by the recharge switching control unit 510, it is possible to detect photons of one pixel even while the other pixel is being recharged, unlike the second comparative example.

FIG. 33 is a diagram illustrating an example of a circuit layout in the detection circuit in the second comparative example. In the second comparative example, the recharge circuit 320 and the AQ pulse generation circuit 340 are arranged in each of the detection circuits 311 and 312. In other words, the recharge circuit 320 and the AQ pulse generation circuit 340 are arranged for each pixel.

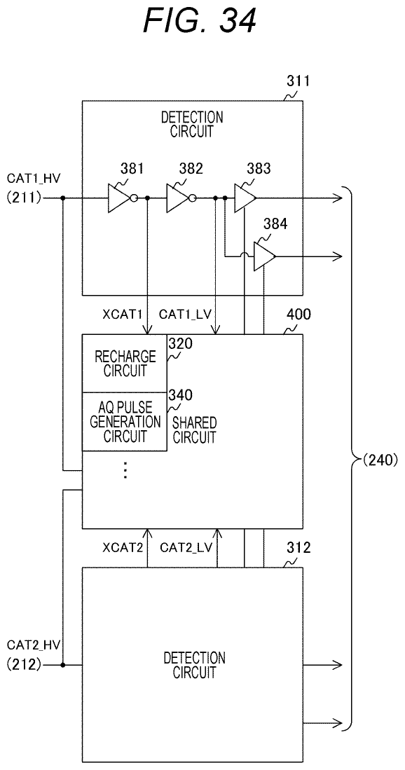

FIG. 34 is a diagram illustrating an example of a circuit layout in the shared circuit 400 in the third embodiment of the present technology. In the third embodiment, the recharge circuit 320 and the AQ pulse generation circuit 340 are arranged in the shared circuit 400, and are shared by two pixels. As described above, since the recharge circuit 320 and the AQ pulse generation circuit 340 are shared by two pixels, the circuit area can be reduced as compared with the second comparative example in which these circuits are arranged for each pixel.

As described above, according to the third embodiment of the present technology, since the recharge circuit 320 and the AQ pulse generation circuit 340 are further shared by a plurality of pixels, the circuit area per pixel can be further reduced.

### Modification

In the third embodiment described above, in the first embodiment described above, the AR pulse generation circuit 330 starts the active recharging when the active quench period has elapsed, but the present invention is not limited to this control. The photodetection element 200 in the third embodiment is different from that of the third embodiment in that the photodetection element 200 starts active recharging even when the connection destination is switched in addition to when the active quench period has elapsed.

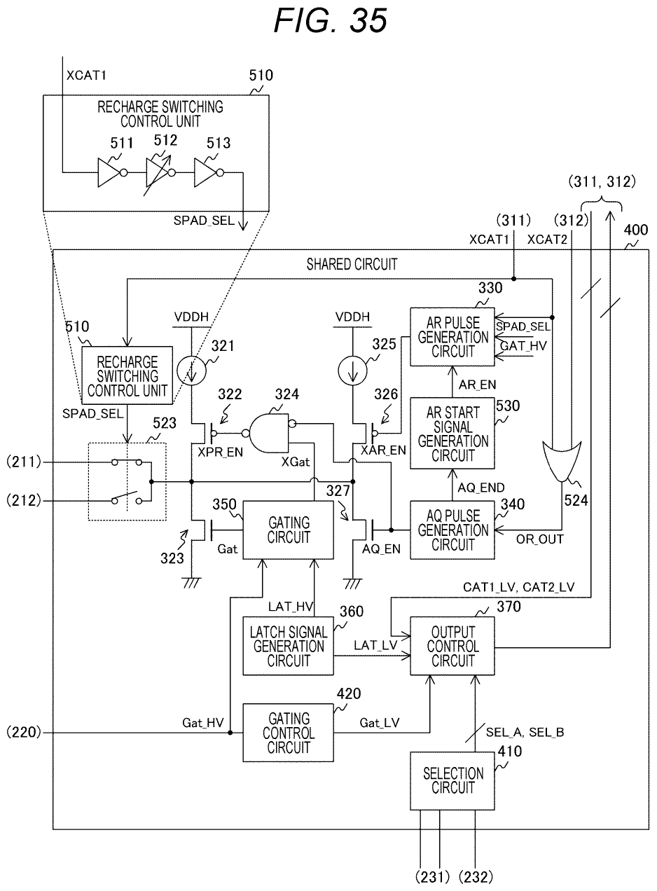

FIG. 35 is a circuit diagram illustrating a configuration example of the shared circuit 400 in a modification of the third embodiment of the present technology. The shared circuit 400 of the modification of the third embodiment is different from that of the third embodiment in further including an AR start signal generation circuit 530. A circuit configuration of the AR start signal generation circuit 530 will be described later.

Furthermore, in a modification of the third embodiment, the recharge switching control unit 510 includes inverters 511, 512, and 513. The inverters 511, 512, and 513 are connected in series. The inverted signal XCAT1 from the detection circuit 311 is input to an input terminal of the inverter 511. The inverters 511, 512, and 513 invert and delay the inverted signal XCAT1 and supply, as the switching signal SPAD_SEL, the result to the recharge switching switch 523. Therefore, the switching signal SPAD_SEL is switched after a certain delay time has elapsed after the inverted signal of the cathode voltage of one of the two pixels exceeds the threshold and becomes a high level, and the other pixel is selected.

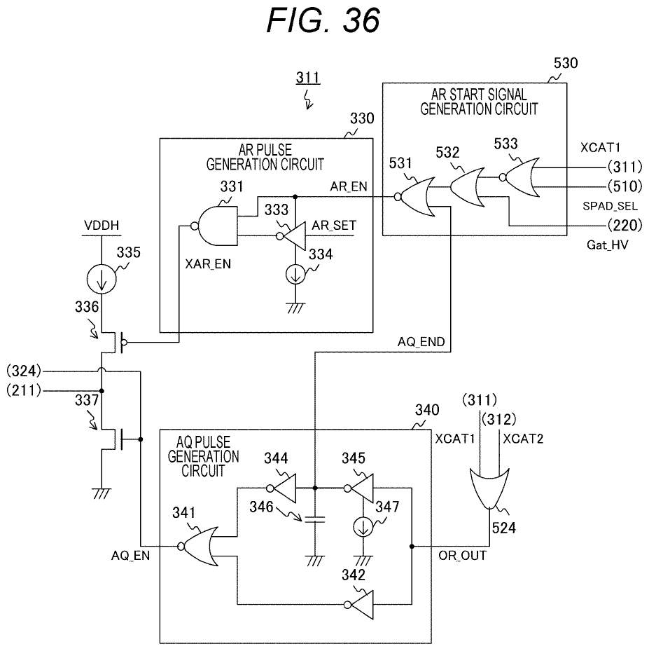

FIG. 36 is a circuit diagram illustrating a configuration example of the AR start signal generation circuit 530 in the modification of the third embodiment of the present technology. The AR start signal generation circuit 530 includes a NOR gate 531, an OR gate 532, and a NOR gate 533.

The NOR gate 533 outputs a logical sum of the inverted signal XCAT1 from the detection circuit 311 and the switching signal SPAD_SEL from the recharge switching control unit 510 to the OR gate 532. The OR gate 532 outputs a logical sum of the gating pulse Gat_HV from the timing generation unit 220 and the output signal of the NOR gate 533 to the NOR gate 531. The NOR gate 531 supplies, as the AR start signal AR_EN, a negative OR of the AQ end signal AQ_END from the AQ pulse generation circuit 340 and the output signal of the OR gate 532 to the AR pulse generation circuit 330.

The AR pulse generation circuit 330 generates the AR enable signal XAR_EN on the basis of the AR start signal AR_EN.

With the circuit configuration illustrated in the drawing, the high-level AR start signal AR_EN is generated when the active quench period has elapsed or when the connection destination to the recharge circuit 320 is switched from the photoelectric conversion element 211 to the photoelectric conversion element 212.

When the AR start signal AR_EN rises, the AR pulse generation circuit 330 generates the low-level AR enable signal XAR_EN over a pulse period and performs active recharging.

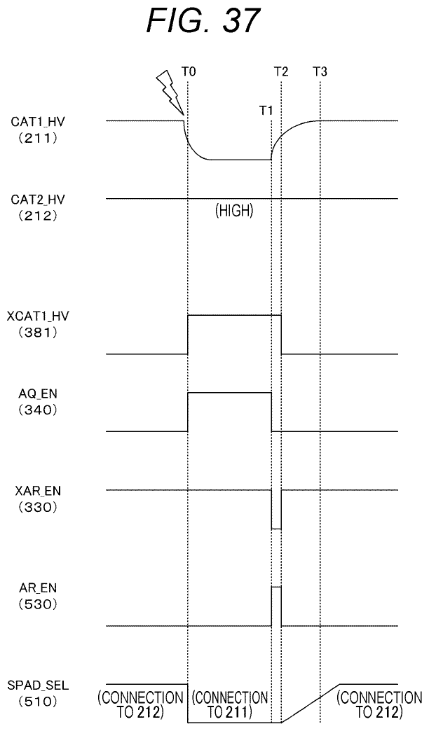

FIG. 37 is a timing chart illustrating an example of an operation of the shared circuit 400 when one of two pixels detects photons in the modification of the third embodiment of the present technology. It is assumed that photons are incident on the first pixel corresponding to the photoelectric conversion element 211, and the cathode voltage CAT1_HV drops at timing T0. The first pixel is charged by the active recharging from timing T1 to timing T2 after the active quench period has elapsed. Then, the switching signal SPAD_SEL returns to a high level at timing T3 after the active recharging, and the second pixel corresponding to the photoelectric conversion element 212 is connected to the recharge circuit 320.

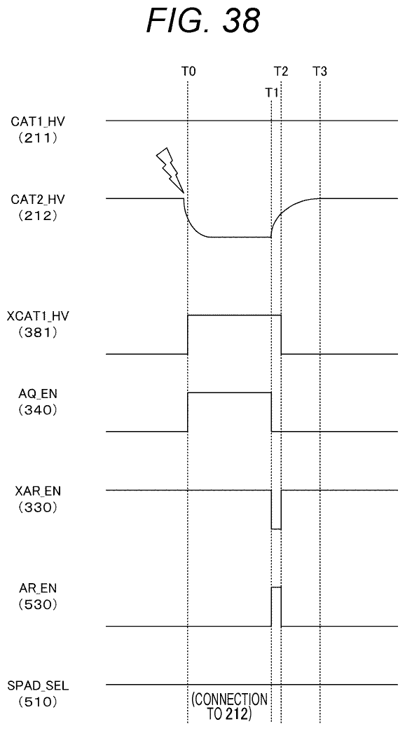

FIG. 38 is a timing chart illustrating an example of an operation of the shared circuit when one of two pixels detects photons in the modification of the third embodiment of the present technology. It is assumed that photons are incident on the second pixel and the cathode voltage CAT2_HV drops at timing T0. The second pixel is charged by active recharging from timing T1 to timing T2 after the active quench period has elapsed. The switching signal SPAD_SEL remains at a high level, and the connection destination of the recharge circuit 320 is not switched.

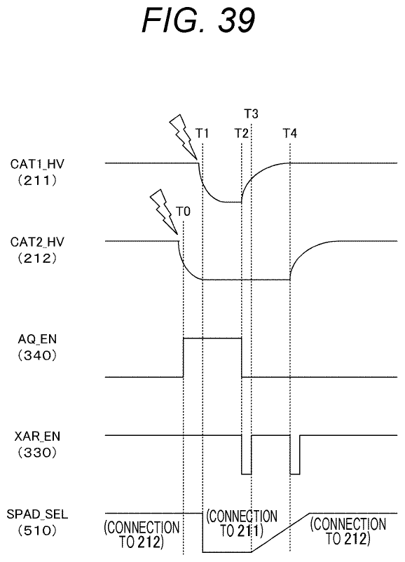

FIG. 39 is a timing chart illustrating an example of an operation of the shared circuit when the other reacts within the active quench period of one of the two pixels in the modification of the third embodiment of the present technology.

It is assumed that the second pixel reacts to the incidence of photons at timing T0, and the first pixel reacts to the incidence of photons at timing T1 within the active quench period. In the circuit configuration illustrated in FIG. 36, a pulse of the AR enable signal XAR_EN is generated from the logical sum of the inverted signals of the pixels from the OR gate 524. Therefore, a pulse of the AR enable signal XAR_EN is not newly generated, and the active recharging of the first pixel is performed in a period from timing T2 to timing T3 after the short active quench period. At timing T4 after that, the active recharging of the second pixel is performed.

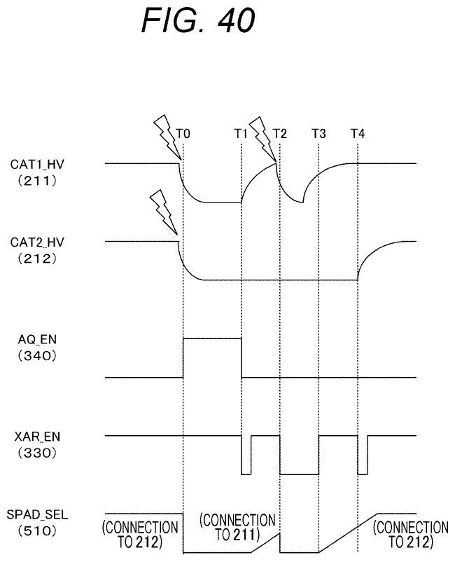

FIG. 40 is a timing chart illustrating an example of an operation of the shared circuit 400 in a case where photons are incident on two pixels almost simultaneously and then photons are incident on one pixel in the modification of the third embodiment of the present technology.

Since the two pixels simultaneously react at timing T0, the shared circuit 400 performs active recharging of the first pixel from timing T1. After the end of the active recharging, the first pixel reacts at timing T2 before the start of the active recharging of the second pixel. Also in this case, a pulse of the AQ enable signal XAQ_EN is not newly generated, and the active recharging of the first pixel is immediately performed after timing T2.

However, when active quenching is not performed, there is a high possibility that latching, which is a problem that the cathode voltage stagnates at a certain value, occurs. Moreover, the dead time of the second pixel also increases. In order to prevent this, it is necessary to set the delay time in the shared circuit 400 to be short so that the active recharging of the second pixel is performed immediately at timing T4 after timing T2 of active recharging completion.

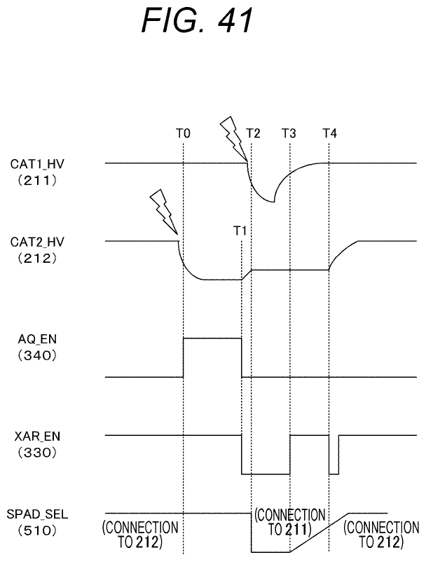

FIG. 41 is a timing chart illustrating an example of an operation of the shared circuit 400 when the other reacts during recharging of one of two pixels in the modification of the third embodiment of the present technology.

Since the second pixel has reacted at timing T0, the shared circuit 400 starts active recharging of the pixel after timing T1. It is assumed that the first pixel reacts at timing T2 during the active recharging. In this case, by switching the connection destination of the recharge circuit 320 at timing T3, the active recharging of the first pixel is stopped in the middle, and the active recharging of the second pixel is started. At timing T4 after that, the active recharging of the first pixel stopped in the middle is restarted.

As described above, according to the modification of the third embodiment of the present technology, the high-level AR start signal AR_EN is generated when the active quench period has elapsed or the connection destination is switched.

### 4. Example of Application to Mobile Body

The technology according to the present disclosure (the present technology) can be applied to various products. For example, the technology according to the present disclosure may be implemented in the form of a device to be mounted on a mobile body of any kind, such as an automobile, an electric vehicle, a hybrid electric vehicle, a motorcycle, a bicycle, a personal mobility, an airplane, a drone, a vessel, or a robot.

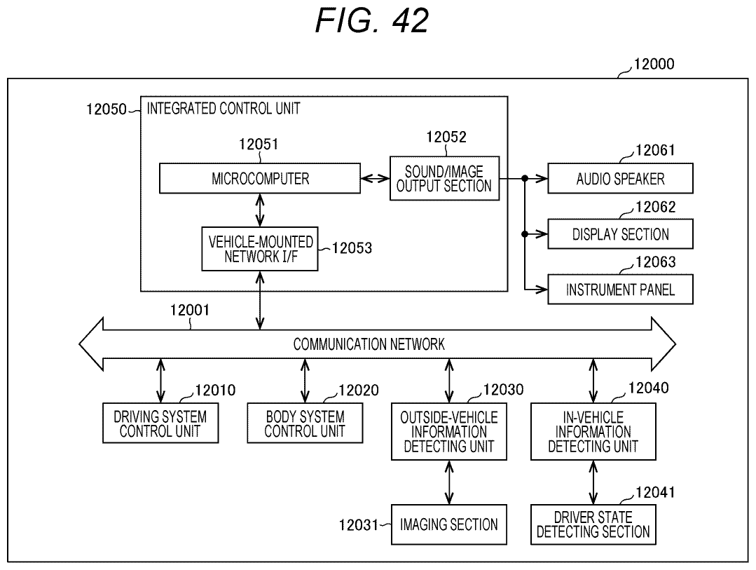

FIG. 42 is a block diagram illustrating an example of a schematic configuration of a vehicle control system that is an example of a mobile body control system to which the technology according to the present disclosure can be applied.

The vehicle control system 12000 includes a plurality of electronic control units connected to each other via a communication network 12001. In the example depicted in FIG. 42, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are depicted as functional components of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020, on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 42, an audio speaker 12061, a display section 12062, and an instrument panel 12063 are illustrated as the output device. The display section 12062 may, for example, include at least one of an on-board display and a head-up display.

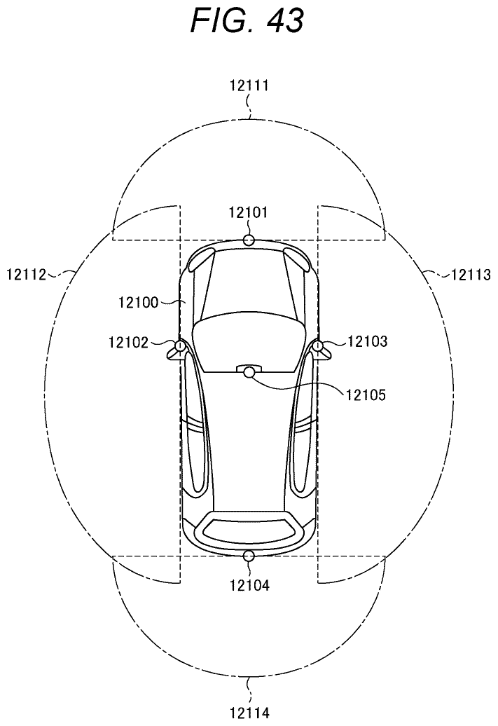

FIG. 43 is a diagram depicting an example of the installation position of the imaging section 12031.

In FIG. 43, the imaging section 12031 includes imaging sections 12101, 12102, 12103, 12104, and 12105.

The imaging sections 12101, 12102, 12103, 12104, 12105 are provided, for example, at positions such as a front nose, a sideview mirror, a rear bumper, a back door, and an upper portion of a windshield in the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly images of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that, FIG. 43 illustrates an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the outside-vehicle information detecting unit 12030 among the components described above. Specifically, the distance measuring module 100 in FIG. 1 can be applied to the outside-vehicle information detecting unit 12030. By applying the technology according to the present disclosure to the outside-vehicle information detecting unit 12030, it is possible to reduce the circuit area and reduce the cost and power consumption of the unit.

Note that the embodiments described above show examples for embodying the present technology, and the respective matters in the embodiments and the respective matters specifying the invention in the claims have correspondence relationships. Similarly, the matters specifying the invention in the claims and the matters with the same names in the embodiments of the present technology have correspondence relationships, respectively. However, the present technology is not limited to the embodiments, and can be embodied by applying various modifications to the embodiments without departing from the scope of the present technology.

Note that the effects described in the present specification are merely examples and are not limited, and other effects may also be achieved.

Note that the present technology may also have the following configuration.
(1) A photodetection device including:
a first detection circuit that detects incidence of photons on the basis of a voltage of one of an anode and a cathode of a first photoelectric conversion element within a period not corresponding to a predetermined detection stop period;
a second detection circuit that detects incidence of photons on the basis of a voltage of one of an anode and a cathode of a second photoelectric conversion element within a period not corresponding to the detection stop period; and
a shared circuit that controls a voltage of a gating pulse indicating the detection stop period.
(2) The photodetection device according to (1), in which
the first and second detection circuits output at least one of a first pulse signal or a second pulse signal according to a selection signal in a case where incidence of photons is detected, and
the shared circuit includes
a gating control circuit that controls a voltage of the gating pulse, and
a selection circuit that generates the selection signal and supplies the selection signal to the first and second detection circuits.
(3) The photodetection device according to (2), in which
the gating control circuit includes
a pre-stage inverter that inverts the gating pulse and outputs an inverted signal, and
a post-stage inverter that inverts the inverted signal and supplies a result to the first and second detection circuits, and
power supply voltages of the pre-stage inverter and the post-stage inverter are different from each other.
(4) The photodetection device according to (2), in which
the gating control circuit includes
an inverter that inverts the gating pulse and outputs the inverted gating pulse as an enable signal,
a logic gate that performs a logic operation on a pulse signal from each of the first and second detection circuits and outputs an operation result, and
a flip-flop that supplies a signal at a predetermined level to the first and second detection circuits in synchronization with the operation result in a case where the enable signal has a predetermined value.
(5) The photodetection device according to (1), in which
the shared circuit further includes
a recharge circuit that performs recharging of one of the first and second photoelectric conversion elements,
an active quench switch that connects the recharge circuit and a reference voltage within the active quench period according to an active quench enable signal indicating a predetermined active quench period, and
an active quench pulse generation circuit that generates the active quench enable signal.
(6) The photodetection device according to (5), further including
a recharge switching switch that selects one of the first and second photoelectric conversion elements and connects the selected one to the recharge circuit), in which
the recharge circuit includes
an active recharge current source,
a passive recharge current source,
an active recharge switch that opens and closes a path between the active recharge current source and the recharge switching switch according to an active recharge enable signal, and
a passive recharge switch that opens and closes a path between the passive recharge current source and the recharge switching switch, and
the shared circuit further includes an active recharge pulse generation circuit that generates the active recharge enable signal.
(7) The photodetection device according to (6), in which
the shared circuit further includes
an active recharge start signal generation circuit that generates an active recharge start signal when the active quench period has elapsed or when the recharge switching switch is switched, and
the active recharge pulse generation circuit generates the active recharge enable signal on the basis of the active recharge start signal.
(8) The photodetection device according to (1), in which
the detection circuit includes
an active recharge current source,
an active recharge switch that opens and closes a path between the active recharge current source and a predetermined node according to an active recharge enable signal,
an active quench switch that connects the predetermined node and a reference voltage within a predetermined active quench period, and
an active recharge pulse generation circuit that generates the active recharge enable signal when the detection stop period has elapsed or when the active quench period has elapsed.
(9) The photodetection device according to any one of (1) to (8), in which
the photoelectric conversion element is a single-photon avalanche diode (SPAD).
(10) A distance measuring device including:
a light emitting unit; and
a photodetection element including a first detection circuit that detects incidence of photons on the basis of a voltage of one of an anode and a cathode of a first photoelectric conversion element within a period not corresponding to a predetermined detection stop period, a second detection circuit that detects incidence of photons on the basis of a voltage of one of an anode and a cathode of a second photoelectric conversion element within a period not corresponding to the detection stop period, a shared circuit that controls a voltage of a gating pulse indicating the detection stop period, and a distance measuring unit that performs distance measurement on the basis of a light emission timing of the light emitting unit and an incidence timing of the photons detected by each of the first and second detection circuits.
(11) A method for controlling a photodetection device, the method including:
a first detection procedure in which a first detection circuit detects incidence of photons on the basis of a voltage of one of an anode and a cathode of a first photoelectric conversion element within a period not corresponding to a predetermined detection stop period;
a second detection procedure in which a second detection circuit detects incidence of photons on the basis of a voltage of one of an anode and a cathode of a second photoelectric conversion element within a period not corresponding to the detection stop period; and
a control procedure in which a shared circuit controls a voltage of a gating pulse indicating the detection stop period.

### REFERENCE SIGNS LIST

100 Distance measuring module
110 Light emitting unit
120 Synchronization control unit
200 Photodetection element
201 Pixel chip
202 Circuit chip
210 Light receiving unit
211 to 214 Photoelectric conversion element
220 Timing generation unit
231 H decoder
232 V decoder
240 Multiplexer
241, 242, 411, 423, 524, 532 Logical sum (OR) gate
250 Time-to-digital converter
260 Histogram generation unit
270 Output interface
300 Circuit block
311 to 314 Detection circuit
320 Recharge circuit
321 PR current source
322 PR switch
323 Gating switch
324 PR pulse generation circuit
325 AR current source
326 AR switch
327 AQ switch
330 AR pulse generation circuit
331, 351 Negative AND (NAND) gate
332, 333, 342, 344, 345, 381, 382, 421, 422, 511 to 513 Inverter
334, 347 Current source
340 AQ pulse generation circuit
341, 352, 521, 531, 533 Negative OR (NOR) gate
343 Delay circuit
346 Capacitive element
350 Gating circuit
360 Latch signal generation circuit
361, 412 Latch circuit
362 Level shifter
370 Output control circuit
371 Flip-flop
372 to 374, 522 Logical product (AND) gate
383, 384 Buffer
400 Shared circuit
410 Selection circuit
420 Gating control circuit
510 Recharge switching control unit
523 Recharge switching switch
530 AR start signal generation circuit
12030 Outside-vehicle information detecting unit

1. A photodetection device comprising:
a first detection circuit that detects incidence of photons on a basis of a voltage of one of an anode and a cathode of a first photoelectric conversion element within a period not corresponding to a predetermined detection stop period;
a second detection circuit that detects incidence of photons on a basis of a voltage of one of an anode and a cathode of a second photoelectric conversion element within a period not corresponding to the detection stop period; and
a shared circuit that controls a voltage of a gating pulse indicating the detection stop period.

2. The photodetection device according to claim 1, wherein
the first and second detection circuits output at least one of a first pulse signal or a second pulse signal according to a selection signal in a case where incidence of photons is detected, and
the shared circuit includes
a gating control circuit that controls a voltage of the gating pulse, and
a selection circuit that generates the selection signal and supplies the selection signal to the first and second detection circuits.

3. The photodetection device according to claim 2, wherein
the gating control circuit includes
a pre-stage inverter that inverts the gating pulse and outputs an inverted signal, and
a post-stage inverter that inverts the inverted signal and supplies a result to the first and second detection circuits, and
power supply voltages of the pre-stage inverter and the post-stage inverter are different from each other.

4. The photodetection device according to claim 2, wherein
the gating control circuit includes
an inverter that inverts the gating pulse and outputs the inverted gating pulse as an enable signal,
a logic gate that performs a logic operation on a pulse signal from each of the first and second detection circuits and outputs an operation result, and
a flip-flop that supplies a signal at a predetermined level to the first and second detection circuits in synchronization with the operation result in a case where the enable signal has a predetermined value.

5. The photodetection device according to claim 1, wherein
the shared circuit further includes
a recharge circuit that performs recharging of one of the first and second photoelectric conversion elements,
an active quench switch that connects the recharge circuit and a reference voltage within the active quench period according to an active quench enable signal indicating a predetermined active quench period, and
an active quench pulse generation circuit that generates the active quench enable signal.

6. The photodetection device according to claim 5, further comprising
a recharge switching switch that selects one of the first and second photoelectric conversion elements and connects the selected one to the recharge circuit, wherein
the recharge circuit includes
an active recharge current source,
a passive recharge current source,
an active recharge switch that opens and closes a path between the active recharge current source and the recharge switching switch according to an active recharge enable signal, and
a passive recharge switch that opens and closes a path between the passive recharge current source and the recharge switching switch, and
the shared circuit further includes an active recharge pulse generation circuit that generates the active recharge enable signal.

7. The photodetection device according to claim 6, wherein
the shared circuit further includes
an active recharge start signal generation circuit that generates an active recharge start signal when the active quench period has elapsed or when the recharge switching switch is switched, and
the active recharge pulse generation circuit generates the active recharge enable signal on a basis of the active recharge start signal.

8. The photodetection device according to claim 1, wherein
the detection circuit includes
an active recharge current source,
an active recharge switch that opens and closes a path between the active recharge current source and a predetermined node according to an active recharge enable signal,
an active quench switch that connects the predetermined node and a reference voltage within a predetermined active quench period, and
an active recharge pulse generation circuit that generates the active recharge enable signal when the detection stop period has elapsed or when the active quench period has elapsed.

9. The photodetection device according to claim 1, wherein
the photoelectric conversion element is a single-photon avalanche diode (SPAD).

10. A distance measuring device comprising:
a light emitting unit; and
a photodetection element including a first detection circuit that detects incidence of photons on a basis of a voltage of one of an anode and a cathode of a first photoelectric conversion element within a period not corresponding to a predetermined detection stop period, a second detection circuit that detects incidence of photons on a basis of a voltage of one of an anode and a cathode of a second photoelectric conversion element within a period not corresponding to the detection stop period, a shared circuit that controls a voltage of a gating pulse indicating the detection stop period, and a distance measuring unit that performs distance measurement on a basis of a light emission timing of the light emitting unit and an incidence timing of the photons detected by each of the first and second detection circuits.

11. A method for controlling a photodetection device, the method comprising:
a first detection procedure in which a first detection circuit detects incidence of photons on a basis of a voltage of one of an anode and a cathode of a first photoelectric conversion element within a period not corresponding to a predetermined detection stop period;
a second detection procedure in which a second detection circuit detects incidence of photons on a basis of a voltage of one of an anode and a cathode of a second photoelectric conversion element within a period not corresponding to the detection stop period; and
a control procedure in which a shared circuit controls a voltage of a gating pulse indicating the detection stop period.
